(19) United States
(12) Patent Application Publication
(10) Pub. No.: US 2007/0092804 A1
(43) Pub. Date: Apr. 26, 2007

(54) Photopolymerizable medium comprising siloxane compounds that support cationic polymerization for holographic storage

(76) Inventors: Eric S. Kolb, Acton, MA (US); Richard A. Minns, Arlington, MA (US); Erdem A. Cetin, San Diego, CA (US); Chunming Wang, Tewksbury, MA (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 11/582,834

(22) Filed: Oct. 18, 2006

Related U.S. Application Data
(60) Provisional application No. 60/728,941, filed on Oct. 18, 2005.

(51) Int. Cl. G03F 7/00; C07F 7/10; C07F 7/04

(52) U.S. Cl. 430/2; 556/413; 556/443

(57) ABSTRACT

Compound represented by structural formulas (XII) and (XV): 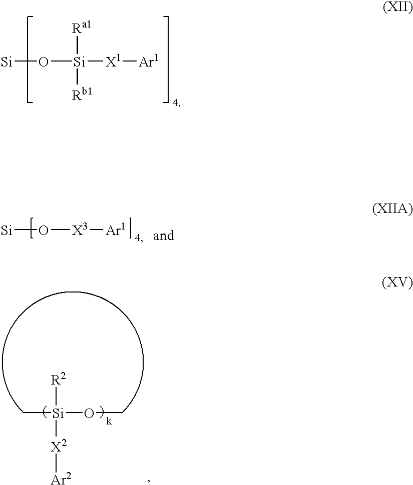 and polymerizable and holographic recording media comprising same. Variables for structural formulas (XII), (XIIA), and (XV) are defined herein.

### RELATED APPLICATION

This application claims the benefit of U.S. Provisional Application Ser. No. 60/728,941 filed on Oct. 18, 2005. The entire teachings of the above application are incorporated herein by reference.

### BACKGROUND OF THE INVENTION

In prior art processes for formation of volume-phase holograms in photopolymerizable materials, data is stored as holograms resulting from the interference of signal and reference beams within a holographic recording medium comprising a homogeneous mixture of at least one polymerizable monomer or oligomer and a polymeric or oligomeric binder; wherein the polymerizable monomer or oligomer is sensitive to, or alternatively is sensitized to the radiation used to form the interference pattern. In the illuminated regions of the interference pattern, the monomer or oligomer undergoes polymerization to form a polymer that has a refractive index different from that of the binder. The polymer exhibits a change in refractive index from the monomer which arises from volume shrinkage. Diffusion of the monomer or oligomer into the illuminated regions, with consequent chemical segregation of binder from these areas and its concentration in the non-illuminated regions, produces spatial separation between the polymer formed from the monomer or oligomer and the binder, thereby providing the refractive index modulation needed to form a hologram. Typically, after the holographic exposure, a post-imaging blanket exposure of the medium to actinic radiation is required to complete the polymerization of the monomer or oligomer and fix the hologram. When holograms are multiplexed co-locationally, such as by multiple holographic exposures at different angle conditions, a post-imaging blanket exposure of the medium to actinic radiation may also be required to complete the polymerization of the monomer or oligomer and fix the multiplexed holograms. In cases when the recording chemistry comprises cationic polymerization then such fixing steps have not been necessary when the recording schedule provides for sufficient total recording fluence.

One important potential use of volume holograms is in digital data storage; the three dimensional nature of a volume hologram, which refers to the storage of each bit as a hologram extending throughout the entire volume of the recording medium, renders volume holograms suitable for use in high capacity digital data storage. A group of bits can be encoded and decoded together as a two dimensional array of bits referred to as a page. Various multiplexing methods, such as angular, spatioangular, shift, wavelength, phase-code, and related methods, are used to store multiple pages co-locationally within the same volume or in partially overlapping volumes. Alternatively, arrays of microholograms can be recorded in layers that are separated in the thickness direction by about the thickness of the microhologram, wherein each layer comprises data stored as bits, such as reflection holograms, at a density similar to that achieved with DVD optical storage. Microholograms can also be multiplexed in a location such as by wavelength.

Photopolymerizable holographic recording media for write-once-read-many (WORM) data storage applications should ideally exhibit pre-recording shelf life of at least a year, good recording sensitivity, high degree of optical homogeneity (i.e. low scattering), uniform recording characteristics, stable image fidelity, and low volume shrinkage coupled with high dynamic range or cumulative grating strength. Stable image fidelity is paramount to having an archival product for storage of information. The holographic recording attributes such as the signal to noise ratio (SNR), the bit error rate (BER), and the Bragg selectivity must be maintained throughout the life of the media for data to be dependably retrievable in the future. Further, the physical attributes of the media must be maintained. For instance, media with recorded information can not crack or delaminate, and preferably should not exhibit changes in its optical properties such as those related to increasing scatter or absorbance.

Diffusible binders have been employed in holographic recording materials based upon cationic ring opening polymerization to achieve high recording sensitivity in combination with high dynamic range (see for example U.S. Patent No. 5,759,721, EP 1 317 498 B1 and U.S. Patent No. 6,784,300). In such cases monomers are combined with a binder material having specific qualifications so as to achieve the desired performance attributes for plane-wave and/or binary data page recording. These binders have typically been linear siloxane oligomer materials of low to moderate molecular weight comprising pendent phenyl and methyl groups attached directly to the siloxane backbone.

Examples of binders, which are diffusible and inert to polymerization, for use in holographic recording materials are polysiloxanes, due in part to availability of a wide variety of polysiloxanes and the well documented properties of these oligomers and polymers. The physical, optical, and chemical properties of the polysiloxane binder can be adjusted so as to achieve good holographic performance in a recording material inclusive of, for example, attributes such as dynamic range, recording sensitivity, image fidelity, level of light scattering, and data lifetime. The efficiency of holograms recorded in said materials is markedly dependent upon the particular binder employed. Commonly used binders have included poly(methyl phenyl siloxanes) and oligomers thereof. 1,3,5-trimethyl- 1,1,3,5,5-pentaphenyltrisiloxane and other pentaphenyltrimethyl siloxanes are examples. Examples are sold by Dow Corning Corporation under the tradename DOW Corning 705 and DOW Coming 710 and have been found to give efficient holograms.

During holographic recording with the aforementioned materials the monomer(s) and/or oligomer(s) undergoes polymerization to form a polymer that has a refractive index different from that of the binder. Diffusion of the monomer(s) and/or oligomer(s) into the illuminated regions during polymerization reactions, with consequent chemical segregation of binder from these areas and alteration in its concentration in the non-illuminated regions, produces spatial separation between the polymer formed from the monomer(s) and/or oligomer(s) and the binder thereby providing the refractive index modulation needed to form a hologram. The chemical segregation and resulting refractive index modulation is primarily due to the molecular weight build-up of the reactive moieties during their polymerization in the matrix of the recording material components and the difference in refractive index between the formed polymer structure and the binder. As the molecular weight increases the diffusible binder is “pushed out” of that particular region due in part to forces related to the gradient in the thermodynamic chemical potential. Concomitantly, the increase of molecular weight can impact the solubility parameter of the binder with other components in the recording material. This physical chemical change can effect partial exudation of the diffusible components from the holographic material which can impact the spatial segregation responsible for hologram formation and may also perturb the interaction of the material with a substrate such as the strength of adhesion to the substrate.

Although nominal exudation of diffusible binder from the recording material has minimal impact on the reliability of the recorded hologram, substantial exudation can lead to a number of reliability issues associated with the mechanical properties of the recording material and the nature of its interface with substrates that sandwich the material. Primarily, the exudation can cause delamination of the media substrate from the recording material. Further, as the binder exudes from the recording material the polymerized regions, originally swelled or imbibed with the binder, can become brittle and cracking can initiate and form. This response to loss of binder would be catastrophic for hologram recording of information that is intended to be archival.

While the use of high molecular weight high viscosity binders can alleviate cracking the binder materials must also be sufficiently compatible with the other components of the recording material so that the material exhibits low scatter. For example, recording materials prepared using poly(phenylmethylsiloxane) (Dow Corning 710) as the binder exhibit much diminished likelihood of cracking and exhibit only minor exudation. However, the bulk scattering from recording materials comprising Dow Coming 710 were at least an order of magnitude greater than those prepared with the lower molecular weight counterpart, such as, for example, Dow Coming 705.

### SUMMARY OF THE INVENTION

It has been found that the binders of this invention overcome the aforementioned limitations of holographic recording materials comprising previously known binders, as recording materials comprising the binders of the present invention are substantially free of exudation of said binders and these said binders have high refractive index, are diffusible, are compatible with Cationic Ring Opening Polymerization (CROP), and are miscible with the monomer(s) and/or oligomer(s) used in the CROP holographic recording materials. It has also been found that these said binders maintain a favorable thermodynamic enthalpy of mixing during the holographic recording process so that spatial and chemical segregation is primarily driven by molecular weight build-up during polymerization and so that segregated domains remain thermodynamically stable throughout the recording process and throughout the anticipated life time of the media. It has been further found that recording materials comprising the binders of the present invention remain substantially free of exudation of said binders when the materials are heated to temperatures between 25° C. and 110° C.

In one embodiment, the present invention is a compound represented by structural formula (XII): 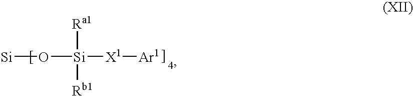
In formula (XII):

X¹, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁—[O—Y₁]ₛ₋, —Y₁—Si(R^{Z})₂—Y₁—, —Y₁—Si(R^{Z})₂—Y₁—O—Y₁—Si(R^{Z})₂—Y₁₋, or —Y₁—Si(R^{Z})₂—Y₁—Si(R^{Z})₂—Y₁₋;

Rₐ₁ and R_{b1}, for each occurrence, are independently an optionally substituted C1-C12 alkyl or optionally substituted C3-C12 cycloalkyl or an optionally substituted aryl or an optionally substituted heteroaryl;

Ar¹, for each occurrence, is independently an optionally substituted aryl or an optionally substituted heteroaryl;

each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;

each Y₁ is independently a covalent bond, or an optionally substituted C1-C12 alkylene group or optionally substituted C3-C12 cycloalkylene or an optionally substituted arylene group or optionally substituted C1-C12 arylalkylene; and

s is 0 or an integer from 1 to 8.

In another embodiment, the present invention is compound represented by structural formula (XV): 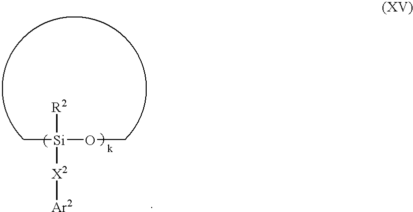
In formula (XV):

R², for each occurrence, is independently an optionally substituted C1-C12 alkyl, an optionally substituted C3-C12 cycloalkyl, or an optionally substituted aryl;

X², for each occurrence, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁—[O—Y₁]ₛ₋, —Y₁—Si(R^{Z})₂—Y₁₋, —Y₁—Si(R^{Z})₂—Y₁—O—Y₁—Si(R^{Z})₂—Y₁₋, or —Y₁—Si(R^{Z})₂—Y₁—Si(R^{Z})₂—Y₁₋;

Ar^{2,} for each occurrence, is independently an optionally substituted aryl or an optionally substituted heteroaryl;

each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;

each Y₁ is independently a covalent bond, or an optionally substituted C1-C12 alkylene group or optionally substituted C3-C12 cycloalkylene or an optionally substituted arylene group or optionally substituted C1-C12 arylalkylene;

k is an integer from 3 to 6; and

s is 0 or an integer from 1 to 8.

In another embodiment, the present invention is a polymerizable media, comprising a) a photo acid generator compound (PAG) which produces acid when exposed to actinic radiation; b) a dye which sensitizes the PAG to produce acid in response to a particular wavelength of light; c) at least one monomer or oligomer which is capable of undergoing cationic polymerization initiated by the acid produced by PAG when exposed to actinic radiation; and d) any of the compounds of formulas (XII) or (XV).

In another embodiment, the present invention is a holographic recording media, comprising: a) a photo acid generator compound (PAG) which produces acid when exposed to actinic radiation; b) a dye which sensitizes the PAG to produce acid in response to a particular wavelength of light; c) at least one monomer or oligomer which is capable of undergoing cationic polymerization initiated by the acid produced by PAG when exposed to actinic radiation; and d) a binder of any of the compounds of formulas (XII) or (XV). Holographic recording media (HRM) are typically characterized by chemical segregation and spatial separation of the binder from a polymer formed from the monomer or oligomer, which produces refractive index modulation within the holographic recording media.

In another embodiment, the present invention is a method of recording holograms within a holographic recording media that comprises a) a photo acid generator compound (PAG) which produces acid when exposed to actinic radiation; b) a dye which sensitizes the PAG to produce acid in response to a particular wavelength of light; c) at least one monomer or oligomer which is capable of undergoing cationic polymerization initiated by the acid produced by PAG when exposed to actinic radiation; and d) a binder of any of the compounds of formulas (XII) or (XV). The method comprises the step of passing into the medium a reference beam of coherent actinic radiation to which the compound which produces acid when exposed to actinic radiation is sensitive and object beam of the same coherent actinic radiation, thereby forming within the medium an interference pattern and thereby recording a hologram within the medium.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a bar plot showing a normalized forward light scattering of polymerized media comprising binders of the current invention versus comparative example of media comprising Dow Corning® 705 fluid as the binder.

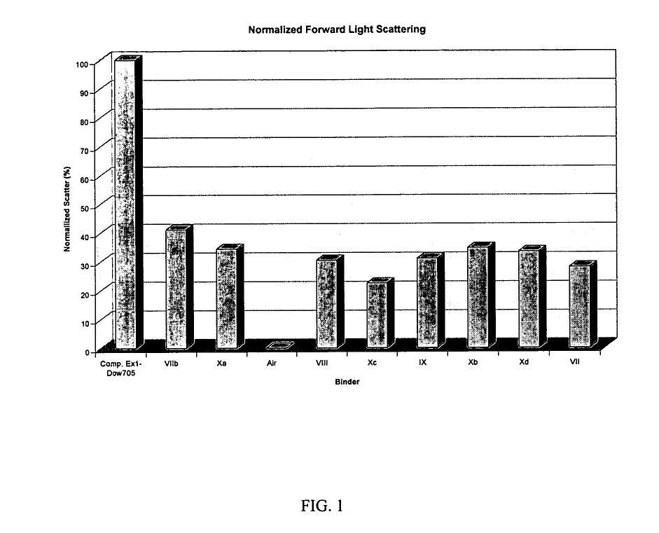

### DETAILED DESCRIPTION OF THE INVENTION

A description of example embodiments of the invention follows.

This invention is directed to binders or diffusible components, such as those used in recording materials for holographic data storage. It has now been found that binders of this invention support cationic polymerization, and further that said binders have a refractive index that is higher than the values for typical epoxide monomers that undergo cationic polymerization. It has been further found that binders of this invention have a molecular composition exhibiting an enthalpy of mixing with epoxide monomers that is favorable for molecular miscibility with said monomers and, additionally, with the polymerized epoxide structures from said monomers. The binders of this invention show said favorable molecular miscibility with epoxide monomers having low functional group equivalent weight, such as about 200 g/mole epoxide, as well as with those having multifunctionality such as those with functional group equivalent weight of at least 300 g/mole epoxide that are the subject of EP 1 317 498 B1 and U.S. Pat. No. 6,784,300, the teachings of which are incorporated herein.

It has been further found that the binders of this invention can be a component of holographic recording materials that comprise epoxide monomers which undergo cationic polymerization, and that the volume scatter of said material is low in both the pre-recorded and post recorded state of the material. It has now also been found that binders of the current invention, as a component in holographic recording materials, have a favorable molecular architecture for the reliability and robustness of the holographic recording material such that these binders do not exude. Additionally, said binders remain substantially soluble or substantially miscible in the holographic material even after substantial polymerization of the monomer(s). Further, it has been found that the holographic recording materials of the current invention, which comprise the binders of the current invention, are substantially resistant to cracking and/or delamination when the material is exposed to elevated temperatures. Binders in this embodiment of the invention increase cohesion in materials comprising epoxide monomers and compounds with other reactive groupings, and thereby improve the robustness and reliability of said materials. The binders of this invention are preferably “diffusible” in holographic recording materials comprising epoxide monomers and/or compounds with other reactive groupings.

One embodiment of the present invention is a holographic recording medium comprising a binder of the present invention capable of supporting cationic polymerization, an acid generator capable of producing an acid upon exposure to actinic radiation and a multifunctional epoxide monomer capable of undergoing cationic polymerization and which has an epoxy equivalent weight greater than about 300 (grams/mole epoxide). As discussed below, certain acid generators also require sensitizers. Preferably, the holographic recording medium additionally comprises a difunctional and/or a monofunctional epoxide monomer capable of undergoing cationic polymerization. Optionally, the monofunctional and difunctional monomer have an epoxy equivalent weight less than about 225 (grams/mole epoxide). The holographic medium of the present invention is preferably essentially free from materials capable of undergoing free radical polymerization.

Another embodiment of the present invention is a polymerizable mixture comprising a binder of the present invention capable of supporting cationic polymerization and a multifunctional epoxide monomer capable of undergoing cationic polymerization and which has an epoxy equivalent weight greater than about 300 grams/mole epoxide. Preferably, the mixture additionally comprises a difunctional and/or monofunctional epoxide monomer capable of undergoing cationic polymerization and which preferably have an epoxy equivalent weight less than about 300 (grams/mole epoxide). This mixture can be used in the preparation of the holographic recording materials of the present invention by adding thereto the other components of the medium, as described below.

Yet another embodiment of the present invention is a method of preparing the holographic recording medium of the present invention without employing a volatile solvent, which necessitates removal of the solvent before the media can be used. Preferably, the media is essentially free of such a solvent, e.g. 99% by weight free of solvent, 99.9% by weight free of solvent or 99.00% by weight free of solvent. As used herein, a volatile solvent is a solvent having the boiling point below about 200_degrees Celsius at ambient pressure. Examples of volatile solvents include acetone, dimethylformamide, hexane, methanol, isopropanol, methylene chloride, tetrahydrofuran, toluene and the like. In prior art volatile solvents have been used to aid in preparation of formulations of a holographic medium and these solvents are then removed from the final medium. The method described herein comprises the step of combining the binders of the present invention, and difunctional and/or multifunctional epoxide monomer(s) and an acid generator. The multifunctional epoxide monomer(s) may preferably have an epoxy equivalent weight greater than about 300 grams/mole epoxide, even more preferably an epoxy equivalent weight between about 300 and about 700 grams/mole epoxide. When present, the sensitizer and the difunctional and/or multifunctional epoxide monomer are also combined therewith. Preferably, the binder and multifunctional epoxide monomer having an epoxy equivalent weight greater than about 300 grams/mole epoxide and, when present, the monofunctional and difunctional monomers are combined first before adding the other components. Alternatively, the sensitizer may be dissolved in the monomer(s) prior to combining with the binder.

Based on these discoveries, novel binders, novel holographic recording materials and methods of preparing these novel holographic recording materials are disclosed herein.

Definitions of Terms The term “aliphatic”, as used herein, means non-aromatic group that consists solely of carbon and hydrogen and may optionally contain one or more units of unsaturation, e.g., double and/or triple bonds. An aliphatic group may be straight chained or branched. One or more carbon atoms in an aliphatic group may optionally be replaced with O or a silicon grouping.

The term “alkyl”, as used herein, unless otherwise indicated, means straight or branched saturated monovalent hydrocarbon radicals, typically C1-C 12, preferably C1- C6. Examples of alkyl groups include, but are not limited to, methyl, ethyl, propyl, isopropyl, and t-butyl. Alkyl can optionally be substituted with —OH, —SH, halogen, amino, cyano, a C1-C12 alkyl, C1-C12 haloalkyl, C1-C12 alkoxy, C1-C12 haloalkoxy or C1-C12 alkyl sulfanyl. In some embodiments, alkyl can optionally be substituted with one or more halogen, hydroxyl, C1-C12 alkyl, C2-C12 alkenyl or C2-C12 alkynyl group, C1-C12 alkoxy, or C1-C12 haloalkyl.

The term “cycloalkyl”, as used herein, means saturated cyclic hydrocarbons, i.e. compounds where all ring atoms are carbons. Examples of cycloalkyl include, but are not limited to, cyclopropyl, cyclobutyl, cyclopentyl, cyclohexyl, and cycloheptyl. In some embodiments, cycloalkyl can optionally be substituted with one or more halogen, hydroxyl, C1-C12 alkyl, C2-C12 alkenyl or C2-C12 alkynyl group, C1-C12 alkoxy, or C1-C12 haloalkyl.

The term “haloalkyl”, as used herein, includes an alkyl substituted with one or more F, Cl, Br, or I, wherein alkyl is defined above.

The terms “alkoxy”, as used herein, means an “alkyl-O—” group, wherein alkyl is defined above. Examples of alkoxy group include methoxy or ethoxy groups.

The term “aryl”, as used herein, refers to a carbocyclic aromatic group. Examples of aryl groups include, but are not limited to phenyl and naphthyl. Examples of aryl groups include optionally substituted groups such as phenyl, biphenyl, naphthyl, phenanthryl, anthracenyl, pyrenyl, fluoranthyl or fluorenyl. Examples of suitable substituents on an aryl include halogen, hydroxyl, C1-C12 alkyl, C2-C12 alkene or C2-C12 alkyne, C3-C12 cycloalkyl, C1-C12 haloalkyl, C1-C12 alkoxy, aryloxy, arylamino or aryl group

The term “aryloxy”, as used herein, means an “aryl-O—” group, wherein aryl is defined above. Examples of an aryloxy group include phenoxy or naphthoxy groups.

The term arylamine, as used herein, means an “aryl-NH—”, an “aryl-N(alkyl)-”, or an “(aryl)₂-N—” groups, wherein aryl and alkyl are defined above.

The term “heteroaryl”, as used herein, refers to aromatic groups containing one or more heteroatoms (O, S, or N). A heteroaryl group can be monocyclic or polycyclic, e.g. a monocyclic heteroaryl ring fused to one or more carbocyclic aromatic groups or other monocyclic heteroaryl groups. The heteroaryl groups of this invention can also include ring systems substituted with one or more oxo moieties. Examples of heteroaryl groups include, but are not limited to, pyridinyl, pyridazinyl, imidazolyl, pyrimidinyl, pyrazolyl, triazolyl, pyrazinyl, quinolyl, isoquinolyl, tetrazolyl, furyl, thienyl, isoxazolyl, thiazolyl, oxazolyl, isothiazolyl, pyrrolyl, quinolinyl, isoquinolinyl, indolyl, benzimidazolyl, benzofuranyl, cinnolinyl, indazolyl, indolizinyl, phthalazinyl, pyridazinyl, triazinyl, isoindolyl, purinyl, oxadiazolyl, thiazolyl, thiadiazolyl, furazanyl, benzofurazanyl, benzothiophenyl, benzotriazolyl, benzothiazolyl, benzoxazolyl, quinazolinyl, quinoxalinyl, naphthyridinyl, dihydroquinolyl, tetrahydroquinolyl, dihydroisoquinolyl, tetrahydroisoquinolyl, benzofuryl, furopyridinyl, pyrolopyrimidinyl, and azaindolyl.

The foregoing heteroaryl groups may be C-attached or N-attached (where such is possible). For instance, a group derived from pyrrole may be pyrrol-1-yl (N-attached) or pyrrol-3-yl (C-attached).

Suitable substituents for heteroaryl are as defined above with respect to aryl group.

As used herein, the term “alkylene” refers to an alkyl group that has two points of attachment to the rest of the compound. Non-limiting examples of alkylene groups include methylene (—CH2-), ethylene (—CH2CH2-), n-propylene (—CH2CH2CH2-), isopropylene (—CH2CH(CH3)-), and the like. Alkylene groups may be optionally substituted with one or more substituents.

As used herein, the term “cycloalkylene” means saturated cyclic hydrocarbon (i.e. all ring atoms are carbons) having two points of attachment to the rest of the compound.

As used herein, the term “arylalkylene” means an aryl group attached to an alkylene or a cycloalkylene group, where aryl, alkylene, and a cycloalkylene are defined above. When referring to the number of carbon atoms in an arylalkylene, the number refers to the alkylene portion of the moiety. For example, a C1-C12 arylalkylene means an aryl group attached to a C1-C12 alkylene or cycloalkylene group.

As used herein, the term “alkenyl” means a saturated straight chain or branched non-cyclic hydrocarbon having from 2 to 12 carbon atoms and having at least one carbon-carbon double bond. Alkenyl groups may be optionally substituted with one or more substituents.

As used herein, the term “alkynyl” means a saturated straight chain or branched non-cyclic hydrocarbon having from 2 to 12 carbon atoms and having at least one carbon-carbon triple bond. Alkynyl groups may be optionally substituted with one or more substituents.

Suitable substituents for an alkyl, alkylene, alkenyl, alkynyl, cycloalkyl, cycloalkenyl, and the alkylene portion of arylalkylene groups include any substituent which 1) does not react under conditions which induce or initiate cationic polymerization of epoxides; 2) does not interfere with acid initiated cationic polymerization of epoxides; 3) and does not interfere with chemical segregation of the binder of the present invention from polymer formed during cationic polymerization of epoxides. Examples of such substituents include a halogen, an alkyl, an alkenyl, a cycloalkyl, a cycloalkenyl, an aryl, a heteroaryl, a haloalkyl, cyano, nitro, haloalkoxy.

Suitable substituents on an aryl, heteroaryl, and aryl portion of arylalkenyl groups include any substituent which 1) does not react under conditions which induce or initiate cationic polymerization of epoxides; 2) does not interfere with acid initiated cationic polymerization of epoxides; 3) and does not interfere with chemical segregation of the binder of the present invention from polymer formed during cationic polymerization of epoxides. An aryl or a heteroaryl may have one or more substituents, which can be identical or different.

Further examples of suitable substituents for a substitutable carbon atom in an aryl, a heteroaryl, or a non-aromatic heterocyclic group include but are not limited to —OH, halogen (—F, —Cl, —Br, and —I), —R, —OR, —CH₂R, —CH₂OR, —CH₂CH₂OR,. Each R is independently an alkyl group.

In some embodiments, suitable substituents for a substitutable carbon atom in an aryl, a heteroaryl or an aryl portion of an arylalkenyl include halogen, hydroxyl, C1-C12 alkyl, C2-C12 alkenyl or C2-C12 alkynyl group, C1-C12 alkoxy, aryloxy group, arylamino group and C1-C12 haloalkyl.

In addition, alkyl, alkenyl, alkynyl, cycloalkyl, alkylene, a heterocyclyl, and any saturated portion of alkenyl, cycloalkenyl, alkynyl, arylalkyl, and heteroaralkyl groups, may also be substituted with ═O, ═S, ═N—R.

Binders of The Present Invention

Two new classes of diffusible binders for hologram recording materials have now been discovered. The diffusible binders can, by way of example, segregate from the polymerizing monomer(s) or oligomer(s) during holographic recording via diffusion-type motion of the binder component. One type of binder comprises a star of a multi-armed (at least 3 arms) siloxane core, wherein the terminus of each arm is a high refractive index moiety, as shown in Structural Formula (I) for the case of a star of a siloxane core with 4 such arms. The refractive index of the terminus of each arm should be at least 1.545, more preferably 1,565, still more preferably 1.585. Thus, in one embodiment, a binder of the present invention comprises a siloxane core with at least three high refractive index moieties. As used herein, the term “multiarmed siloxane core terminated with high refractive index moieties” refers to a composition of matter having the refractive index of at least 1.550, preferably at least 1.600. In a preferred embodiment, refractive index of any one moiety attached as the terminus of an arm to the siloxane core should preferably be at least about 1.545, more preferably at least 1.565, still more preferably at least 1.585. Other binders of this invention comprise a cyclic methyl-siloxane core with pendent aromatic moieties, as shown in Structural Formula (II) wherein n is the number of methylsiloxane units in the cyclic structure. The cyclic siloxane core comprises at least 3 substituted methylsiloxane units. The cyclic siloxane core of this invention is preferably composed of at least 4 repeat units and more preferably the siloxane core comprises a mixture of ring sizes from n=3 to about n=6 repeat units.

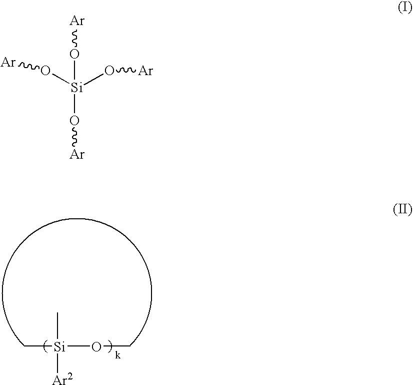

In one embodiment the aromatic moieties, depicted as Ar² in Structural Formula (II), are attached directly to the cyclic siloxane core via a bond to Si. In a preferred embodiment the aromatic moiety is attached to the cyclic siloxane core via a linking group X shown below in Structural Formula (III). The linking group X is preferably an alkyl group comprising an aliphatic grouping —(CH₂)ₘ₋ or substituted aliphatic grouping —(CHR)ₘ₋, where m is a positive integer and R is a substituted or unsubstituted alkyl, cycloalkyl or aromatic grouping (Ar), or the aliphatic grouping —(CH₂)ₘ₋ or the substituted aliphatic grouping —(CHR)ₘ₋ may be replaced by a substituted or unsubstituted alkylene or cycloalkylene grouping. Additionally the linking group may be an alkeneyl group such as would result from the reaction of an arylacetylene, or an arylalkylacetylene, with the cyclic or multi-armed core.

An aliphatic group is a straight chained, branched or cyclic non-aromatic hydrocarbon which is completely saturated or which contains one or more units of unsaturation. Typically, a straight chained or branched aliphatic group has from 1 to about 12 carbon atoms, preferably from 1 to about 8, and a cyclic aliphatic group has from 3 to about 10 carbon atoms, preferably from 3 to about 8. An aliphatic group is preferably a straight chained or branched alkyl group, e.g, methyl, ethyl, n-propyl, isopropyl, n-butyl, sec-butyl, tert-butyl, pentyl, hexyl, heptyl or octyl, or a cycloalkyl group with 3 to about 8 carbon atoms. In one embodiment suitable substituents on an aliphatic group (including, by way of example, an alkylene or alkenyl group or an aryl group, carbocyclic or heteroaryl group) are those which 1) do not react under conditions which induce or initiate cationic polymerization of epoxides; 2) do not interfere with acid initiated cationic polymerization of epoxides; 3) and do not interfere with chemical segregation of the binder of the present invention from polymer formed during cationic polymerization of epoxides unless the substituent group comprises an epoxide moiety or other functional grouping that is suitable for reacting under conditions suitable for cationic polymerization of epoxides.

In one embodiment the linking group, denoted as a wavy line in structural formula (I), and, independently as X¹ and X² in structural formulas (XII) and (III), respectively, is an “inert linking group”, wherein an inert linking group is a moiety which: 1) does not react under conditions which induce or initiate cationic polymerization of epoxides; 2) does not interfere with acid initiated cationic polymerization of epoxides; 3) and does not interfere with chemical segregation of the binder of the present invention from polymer formed during cationic polymerization of epoxides.

Preferably, m repeats in the alkylene grouping of the binder of the present invention is large enough to impart favorable motion of the pendent aromatic moieties for component miscibility without causing significant reduction in the refractive index of the diffusible compound . Alternatively, the linking groups can comprise a hetero atom such as an O, (ether) or Si. In the latter case the Si atom can be substituted with a multitude of groups such as aliphatic, aryl or a mixture of both groups. For example, —CH₂CH₂Si(CH₃)₂-Ar, —CH₂CH₂Si(Ph)₂-Ar or —CH₂CH₂Si(CH₃)Ph-Ar where Ar is an aromatic grouping and Ph is a phenyl group. In the former case, linking groups comprising ether moieties, such as methyloxy, —CH₂—O ethyloxy, —(CH₂)₂—O propyloxy —(CH₂)₃—O—, butyloxy—(CH₂)₄—O and so forth are possible.

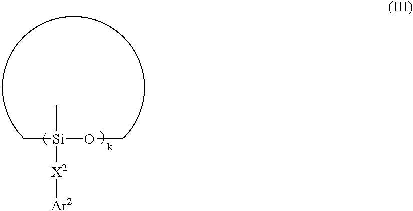

Preferably, one substituent on the unit of the cyclic siloxane core or linker group to the unit of the core is a substituted or unsubstituted aryl group. The aryl group can be a substituted or unsubstituted phenyl, biphenyl, naphthyl, or phenanthryl grouping or mixtures thereof. Larger aryl groups such as, but not limited to, anthracenyl or pyrenyl are also possible.

Accordingly, in one embodiment, the present invention is a binder of formula (XII)

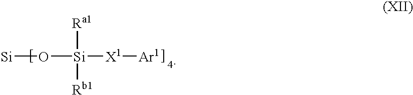

Values and preferred values for the variables in formula (XII) are defined below and are further provided in the following paragraphs.

Preferably, in formula (XII), the substutuents Ar¹, X¹ and R^{a1} and R^{b1} are selected so that the refractive index of said compound is equal to or greater than 1.550 and/or the substutuents Ar¹, X¹ and R^{a1} and R^{b1} are selected so that the viscosity of said compound is equal to or greater than 175 centistokes.

X¹, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁—[O—Y₁]ₛ₋, —Y₁,—Si(R^{Z})₂—Y₁₋, —Y₁—Si(R^{Z})₂—Y₁—O—Y₁—Si(R^{Z})₂—Y₁₋, or —Y₁—Si(R^{Z})₂—Y₁—Si(R^{Z})₂—Y₁₋. Preferably, X¹, for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋. More preferably, X¹ is —(CHR′)ₙ₋, wherein n is from 1 to 12; R′, for each occurrence, is independently: (i) a hydrogen; or (ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or (iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. Even more preferably, R′ is, for each occurrence, independently a hydrogen or a C1-C12 alkyl. In one embodiment, X¹ is —(CH₂)₂₋ or —(CH₂)₃₋. Values and preferred values for the remainder of the variables are as described for formula (XII).

Each Y₁ is independently a covalent bond, or an optionally substituted C1-C12 alkylene group or optionally substituted C3-C12 cycloalkylene or an optionally substituted arylene group or optionally substituted C1-C12 arylalkylene. Preferably, Y₁ is an optionally substituted C1-C12 alkylene or optionally substituted C1-C12 arylalkylene. More preferably, Y₁ is a C1-C12 alkylene. Values and preferred values for the remainder of the variables are as described for formula (XII).

Each R^{Z} is independently an optionally substituted C1-C12 alkyl group, optionally substituted C3-C12 cycloalkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group. Preferably, R^{Z}, is a C1-C12 alkyl or a phenyl substituted with a halogen, hydroxyl, C1-C12 alkyl, C1-C12 alkoxy, and C1-C12 haloalkyl. Values and preferred values for the remainder of the variables are as described for formula (XII).

Ar¹, for each occurrence, is independently an optionally substituted aryl or an optionally substituted heteroaryl. Preferably, Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, C1-C12 alkene or C1-C12 alkyne group, C1-C12 alkoxy, optionally substituted aryloxy, C1-C12 haloalkyl or optionally substituted arylamino. More preferably, Ar¹ for each occurrence, is independently 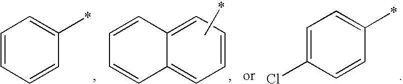
Values and preferred values for the remainder of the variables are as described for formula (XII).

R^{a1} and R^{b1}, for each occurrence, are independently an optionally substituted C1-C12 alkyl or optionally substituted C3-C12 cycloalkyl or an optionally substituted aryl or an optionally substituted heteroaryl. Preferably, R^{a1} and R^{b1}, for each occurrence, are independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. More preferably, R^{a1} and R^{b1}, for each occurrence, are independently a C1-C12 alkyl or a phenyl, optionally substituted with halogen, hydroxyl, C1-C12 alkyl, C2-C12 alkeneyl or C2-C12 alkynyl group, C1-C12 alkoxy, optionally substituted aryloxy group, optionally substituted arylamino group and C1-C12 haloalkyl. Even more preferably, R^{a1} and R^{b1}, for each occurrence, are independently a C1-C12 alkyl or a phenyl, optionally substituted with C1-C3 alkyl, C1-C3 haloalkyl or C1-C3 alkoxy group. Values and preferred values for the remainder of the variables are as described for formula (XII).

s is zero or an integer from 1 to 8.

In one embodiment of formula (XII), at least one group —X¹-Ar¹ is different from the other —X¹-Ar¹ groups in formula (XII). Preferably, at least one Ar¹ group is different from the other Ar¹ groups in structural formula (XII). Values and preferred values for the remainder of the variables are as described for formula (XII).

A first specific embodiment of the present invention is a binder of formula (XX): 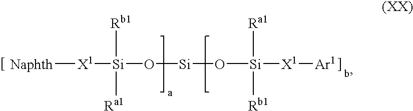
In formula (XX), Naphth is naphthyl, optionally substituted with halogen, hydroxyl, C1-C12 alkyl, C2-C12 alkene or C2-C12 alkyne, C3-C12 cycloalkyl, C1-C12 haloalkyl, C1-C12 alkoxy, optionally substituted aryloxy, optionally substituted arylamino or optionally substituted aryl group and a and b are, independently, positive integers from 1 to 3, such that a+b=4. Values and preferred values for the variables Ar¹, X¹ and R^{a1} and R^{b1} are defined above with respect to formula (XII).

Specific sets of values for the variables in formulas (XII) and (XX) are provided in the following paragraphs:

In a first set of specific values for the variables in formulas (XII) and (XX), X¹, for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋. In one embodiment, Y¹ is as defined above with respect to formula (XII). In another embodiment, Y₁ is a covalent bond, an optionally substituted C1-C12 alkylene or optionally substituted C1-C12 arylalkylene. Values and preferred values for the remainder of the variables are as previously defined with respect to formulas (XII) and (XX).

In a second set of specific values for the variables in formulas (XII) and (XX), X¹, for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋; Y₁ is an optionally substituted C1-C12 alkylene or optionally substituted C1-C12 arylalkylene; and R^{Z} is independently an optionally substituted C1-C12 alkyl group, optionally substituted C3-C12 cycloalkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group. Values and preferred values for the remainder of the variables are as previously defined with respect to formulas (XII) and (XX).

In a third set of specific values for the variables in formulas (XII) and (XX), X¹, for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋; Y₁is an optionally substituted C1-C12 alkylene or optionally substituted C1-C12 arylalkylene; R^{Z} is independently an optionally substituted C1-C12 alkyl group, optionally substituted C3-C12 cycloalkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group; and Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, C1-C12 alkene or C1-C12 alkyne group, C1-C12 alkoxy, optionally substituted aryloxy, C1-C12 haloalkyl or optionally substituted arylamino. Values and preferred values for the remainder of the variables are as previously defined with respect to formulas (XII) and (XX).

In a fourth set of specific values for the variables in formulas (XII) and (XX), X¹, for each occurrence, is independently an optionally substituted C1-C12 alkylene, an optionally substituted C3-C12 cycloalkylene, an optionally substituted C1-C12 arylalkylene, an optionally substituted arylene, —Y₁—Si(R^{Z})₂—Y₁₋; Y₁ is an optionally substituted C1-C12 alkylene or optionally substituted C1-C12 arylalkylene; R^{Z} is independently an optionally substituted C1-C12 alkyl group, optionally substituted C3-C12 cycloalkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group; Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, C1-C12 alkene or C1-C12 alkyne group, C1-C12 alkoxy, optionally substituted aryloxy, C1-C12 haloalkyl or optionally substituted arylamino; R^{a1} and R^{b1}, for each occurrence, are independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. Values and preferred values for the remainder of the variables are as previously defined with respect to formulas (XII) and (XX).

In a fifth set of specific values for the variables in formulas (XII) and (XX), X¹ is —(CHR′)ₙ₋, wherein n is from 1 to 12; R′, for each occurrence, is independently: (i) hydrogen; or (ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or (iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, C1-C12 alkene or C1-C12 alkyne group, C1-C12 alkoxy, optionally substituted aryloxy, C1-C12 haloalkyl or optionally substituted arylamino; and R^{a1} and R^{b1}, for each occurrence, are independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. Values and preferred values for the remainder of the variables are as previously defined with respect to formulas (XII) and (XX).

A second specific embodiment of the present invention is a binder of formula (XXII): 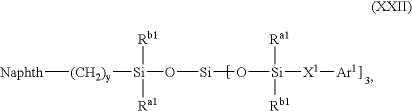
where y is a positive integer from 2 to 6. Values and preferred values for the remainder of the variables are as described for formulas (XII) and (XX).

In a first set of specific values for the variables in formulas (XII) and (XXII), X¹ is —(CHR′)ₙ₋, wherein n is from 1 to 12; R′, for each occurrence, is independently: (i) hydrogen; or (ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or (iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, C1-C12 alkene or C1-C12 alkyne group, C1-C12 alkoxy, optionally substituted aryloxy, C1-C12 haloalkyl or optionally substituted arylamino; and R^{a1} and R^{b1}, for each occurrence, are independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. Values and preferred values for the remainder of the variables are as previously defined with respect to formulas (XII) and (XXII).

In a second set of specific values for the variables in formulas (XII) and (XXII), X¹ is —(CHR′)ₙ₋, wherein n is from 1 to 12; R′, for each occurrence, is independently: (i) hydrogen; or (ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or (iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; and R^{a1} and R^{b1}, for each occurrence, are independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; and Ar¹ for each occurrence, is independently 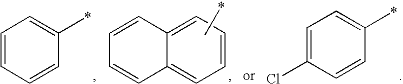
Values and preferred values for the remainder of the variables are as previously defined with respect to formulas (XII) and (XXII).

In a third set of specific values for the variables in formulas (XII) and (XXII), X¹ is —(CH₂)₂₋ or —(CH₂)₃₋; y is 2 or 3; R^{a1} and R^{b1}, for each occurrence, are independently a C1-C12 alkyl or a phenyl, optionally substituted with halogen, hydroxyl, C1-C12 alkyl, C2-C12 alkeneyl or C2-C12 alkynyl group, C1-C12 alkoxy, optionally substituted aryloxy group, optionally substituted arylamino group and C1-C12 haloalky; and Ar¹ for each occurrence, is independently

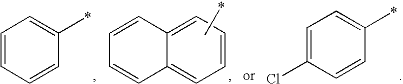

In yet another embodiment, the binder of the present invention is a compound represented by structural formula (XIIA):

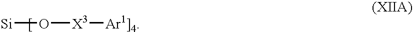

In formula (XIIA), X³ is X¹ or 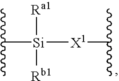
where the values and preferred values for X¹, R^{a1}, R^{b1}, and Ar¹ were defined above for formulas (XII), (XX) and (XXII). In one embodiment of formula (XIIA), at least one group —X³-Ar¹ is different from the other —X³-Ar¹ groups in formula (XIIA). Preferably, at least one Ar¹ group is different from the other Ar¹ groups in structural formula (XIIA). Values and preferred values for the remainder of the variables are as described for formula (XIIA), (XII), (XX) and (XXII).

An example of the compound of formula (XII) is represented by structural formula (XI):

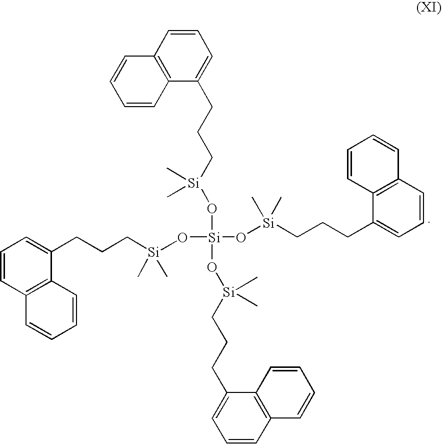

In another embodiment, the present invention is a compound represented by structural formula (XV): 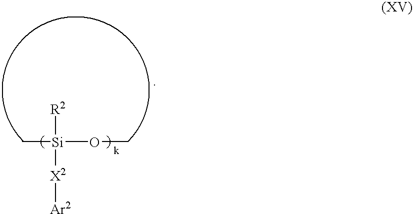
Values and preferred values for the variables in formula (XV) are defined below and are further provided in the paragraphs below.

Preferably, in formula (XV), the substutuents Ar², and X², and the value of variable k are selected so that the refractive index of said compound is equal to or greater than 1.550, and/or the viscosity of said compound is equal to or greater than 175 centistokes.

R², for each occurrence, is independently an optionally substituted C1-C12 alkyl, an optionally substituted C3-C12 cycloalkyl, or an optionally substituted aryl. Preferably, R², for each occurrence, for each occurrence, (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. More preferably, R² is methyl, ethyl, or phenyl, optionally substituted with C1-C3 alkyl, C1-C3 haloalkyl or C1-C3 alkoxy group.

X², for each occurrence, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁—[O—Y₁]ₛ₋, —Y₁—Si(R^{Z})₂—Y₁₋, —Y₁—Si(R^{Z})₂—Y₁—O—Y₁—Si(R^{Z})₂—Y₁₋, or —Y₁—Si(R^{Z})₂—Y₁—Si(R^{Z})₂—Y₁₋. Preferably, X², for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋. More preferably, X² is —(CHR′)ₙ₋, wherein n is from 1 to 12; R′, for each occurrence, is independently: (i) a hydrogen; or (ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or (iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. Even more preferably, X² is —(CH₂)₂₋ or —(CH₂)₃₋. Values and preferred values for the remainder of the variables are as described for formula (XV).

Ar², for each occurrence, is independently an optionally substituted aryl or an optionally substituted heteroaryl. Preferably, Ar2 is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, alkene or alkyne group, C1-C12 alkoxy, optionally substituted aryloxy, C1-C12 haloalkyl or optionally substituted arylamino. In one embodiment, Ar2 is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group. More preferably, Ar² for each occurrence, is independently 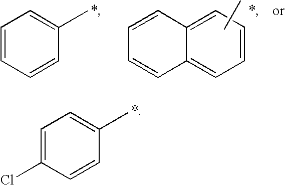
Even more preferably, Ar² is phenyl or 2-naphthyl or 3-chlorophenyl. Values and preferred values for the remainder of the variables are as described for formula (XV).

Each R^{Z} is independently an optionally substituted C1-C12 alkyl group, optionally substituted C3-C12 cycloalkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, a optionally substituted aryloxy group or a optionally substituted diaryl amino group. Preferably, R^{Z}, is a C1-C12 alkyl or a phenyl substituted with a halogen, hydroxyl, C1-C12 alkyl, C1-C12 alkoxy, and C1-C12 haloalkyl. Values and preferred values for the remainder of the variables are as described for formula (XV).

Each Y₁ is independently a covalent bond, or an optionally substituted C1-C12 alkylene group or optionally substituted C3-C12 cycloalkylene or an optionally substituted arylene group or optionally substituted C1-C12 arylalkylene. Preferably, Y₁ is an optionally substituted C1-C12 alkylene or optionally substituted C1-C12 arylalkylene. More preferably, Y₁ is a C1-C12 alkylene. Values and preferred values for the remainder of the variables are as described for formula (XV).

k is an integer from 3 to 6; and s zero or an integer from 1 to 8. Values and preferred values for the remainder of the variables are as described for formula (XV).

In one embodiment of formula (XV), at least one —X²-Ar² group is different from the other —X²-Ar² groups in formula (XV). Preferably, at least one Ar² group is different from the other Ar² groups in structural formula (XV). Values and preferred values for the remainder of the variables are as described for formula (XV).

A first specific embodiment of the present invention is a binder of formula (XVI): 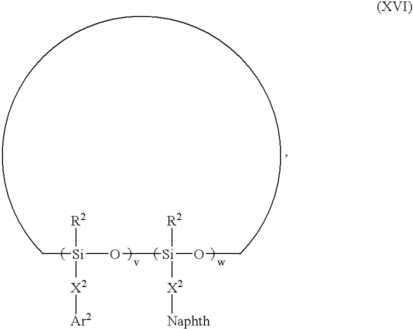
In formula (XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3, 4, 5 or 6. Values and preferred values for the remainder of the values are defined above with respect to formula (XV).

Specific sets of values for the variables in formulas (XV) and (XVI) is provided in the following paragraphs:

In a first set of values for the variables of formulas (XV) and (XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3, 4, 5 or 6; and X², for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋. Values and preferred values for the remainder of the values are defined above with respect to formula (XV).

In a second set of values for the variables of formulas (XV) and (XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3, 4, 5 or 6; and X², for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋; and Y₁ is an optionally substituted C1-C12 alkylene or optionally substituted C1-C12 arylalkylene. Values and preferred values for the remainder of the values are defined above with respect to formula (XV).

In a third set of values for the variables of formulas (XV) and (XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3, 4, 5 or 6; and X², for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋; and Y₁ is an optionally substituted C1-C12 alkylene or optionally substituted C1-C12 arylalkylene; and R^{Z} is independently an optionally substituted C1-C12 alkyl group, optionally substituted C3-C12 cycloalkyl group, or an aryl optionally substituted with a C1-C12 alkyl, alkene or alkyne group, a C1-C12 haloalkyl, a halogen, hydroxyl, a C1-C12 alkoxy group, an optionally substituted aryloxy group or a optionally substituted diaryl amino group. Values and preferred values for the remainder of the values are defined above with respect to formula (XV).

In a fourth set of values for the variables of formulas (XV) and XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3, 4, 5 or 6; and X², for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋; and Y₁ is an optionally substituted C1-C12 alkylene or optionally substituted C1-C12 arylalkylene; and Ar² is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, alkene or alkyne group, C1-C12 alkoxy, optionally substituted aryloxy, C1-C12 haloalkyl or optionally substituted arylamino Values and preferred values for the remainder of the values are defined above with respect to formula (XV).

In a fifth set of values for the variables of formulas (XV) and (XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3, 4, 5 or 6; and X², for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋; and Y₁ is an optionally substituted C1-C12 alkylene or optionally substituted C1-C12 arylalkylene; and Ar² is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, alkene or alkyne group, C1-C12 alkoxy, optionally substituted aryloxy, C1-C12 haloalkyl or optionally substituted arylamino; and R², for each occurrence, for each occurrence, (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl. Values and preferred values for the remainder of the values are defined above with respect to formula (XV).

In a sixth set of values for the variables of formulas (XV) and (XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3, 4, 5 or 6; X² is —(CHR′)ₙ₋, wherein n is from 1 to 12; R′, for each occurrence, is independently: (i) a hydrogen; or (ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or (iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; and R², for each occurrence, for each occurrence, (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; and Ar² is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, alkene or alkyne group, C1-C12 alkoxy, optionally substituted aryloxy, C1-C12 haloalkyl or optionally substituted arylamino. Values and preferred values for the remainder of the values are defined above with respect to formula (XV).

In a seventh set of values for the variables of formulas (XV) and (XVI), Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted optionally substituted aryloxy, optionally substituted arylamino or optionally substituted aryl group, and v and w are positive integers such that the sum of v and w is 3, 4, 5 or 6; X² is —(CHR′)ₙ₋, wherein n is from 1 to 12; R′, for each occurrence, is independently: (i) a hydrogen; or (ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or (iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; and R², for each occurrence, for each occurrence, (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl; and Ar² for each occurrence, is independently 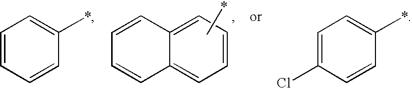
Values and preferred values for the remainder of the values are defined above with respect to formula (XV).

A second specific embodiment of formula (XV) is a binder represented by structural formula (XVII): 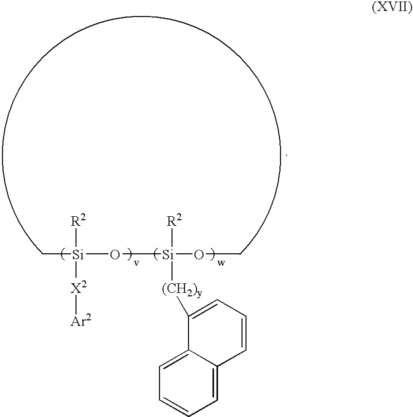
Values and preferred values for the remainder of the values of formula (XVII) are defined above with respect to formulas (XV) and (XVI). Preferably, in formula (XVII), y is a positive integer from 2 to 6.

A third specific embodiment of the present invention is a binder represented by structural formula (X): 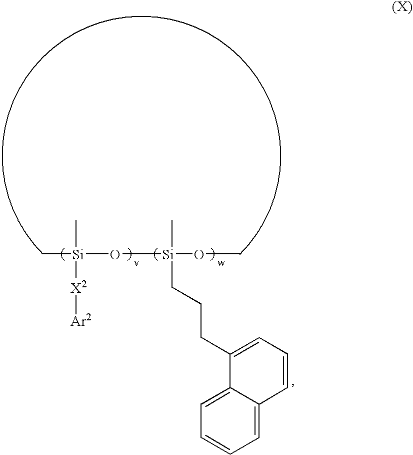
Values and preferred values for the variables in formula (X) are as defined above for formulas (XV), (XVI), and (XVII). Preferably, in formula (X), X² is —(CH₂)₂₋.

In a specific set of values for the variables of formulas (XV), (XVI), (XVII) and (X), X² is —(CH₂)₂₋or —(CH₂)₃₋; and Ar² is phenyl or 2-naphthyl or 3-chlorophenyl; and y is a positive integer from 2 to 6.

In one embodiment, the present invention is also a mixture of the cyclic binders disclosed herein, wherein k is different for each binder. For example, the present invention is a mixture of the compounds of formula (XV), (XVI) and (XVII), where the value of variable k is different for different compounds.

Examples of the compounds of formula (XV) are shown below.

The aromatic moieties of the binders of the present invention, such as those shown in Structural Formula (I), (II) and (III), may be identical, such as a tetraphenyltetramethylcyclotetrasiloxane grouping or tetranaphthylpropyltetramethylcyclotetrasiloxane grouping (see Structural Formula (IV)), or they may be different such as, by way of example, a mixture of naphthyl groups and phenyl groups on the tetracyclo (d4) siloxane core (see Structural Formula (V)) or a cylic siloxane core of other number of repeat units such as 3 or 5, or combinations of different number of repeat units.

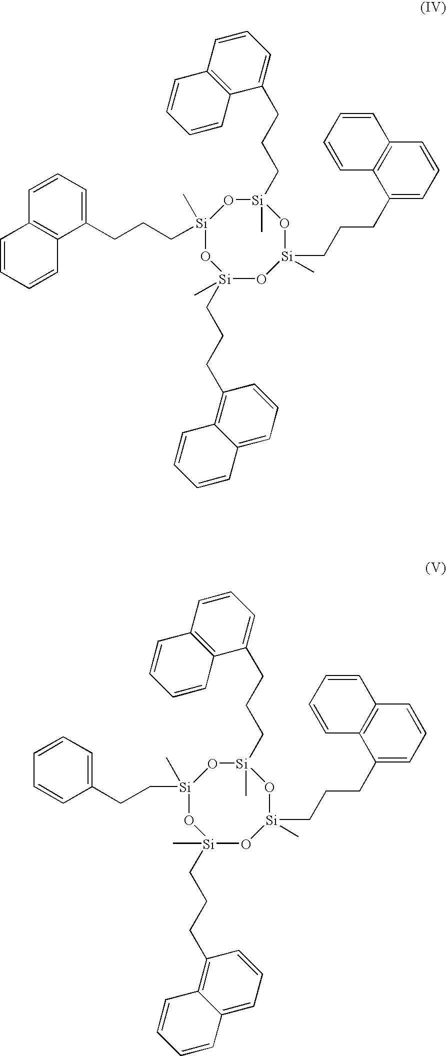

Diffusible binders of the preferred embodiment are accessible via a number of synthetic pathways. Hydrosilylation chemistry is a convenient way to prepare these materials. For example, a cyclic core such as 1,3,5,7-tetravinyl-1,3,5,7-tetramethylcyclotetrasiloxane can be reacted with an aryl substituted hydrosilane such as diphenylmethylsilane to prepare compound of Structural Formula (VI).

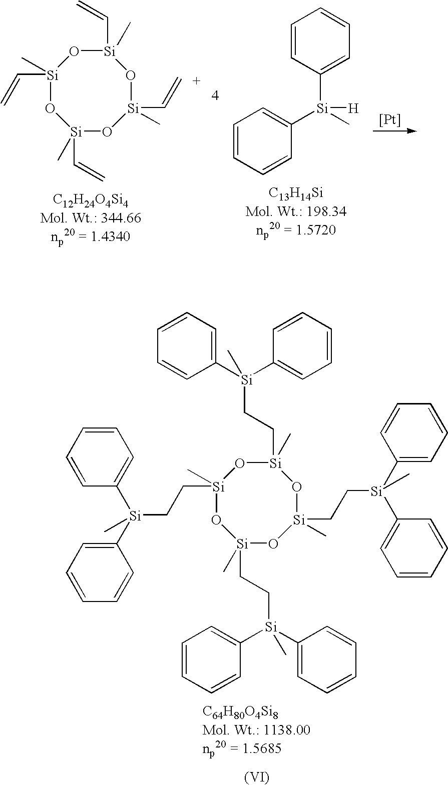

Alternatively, 1,3,5,7-tetramethylcyclotetrasiloxane can be reacted with an arylalkene such 1-allylnaphthalene to prepared binder of Structural Formula (VII).

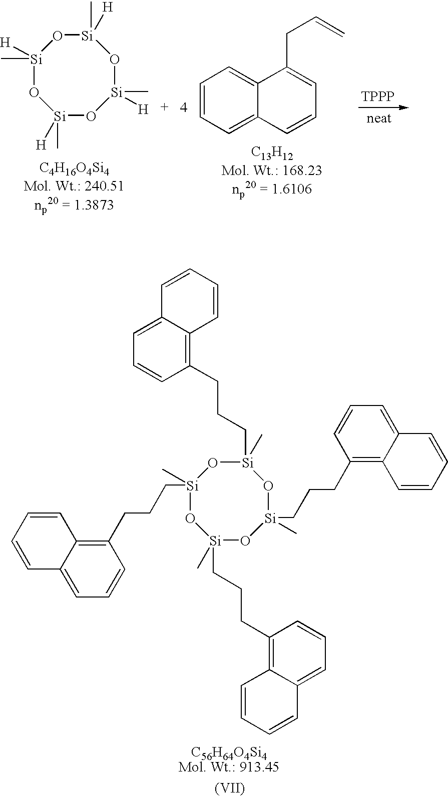

Alternatively, it is optionally also possible to utilize a less well defined staring material such as methylhydrocyclosiloxanes to yield a distribution of ring sizes in the binder material. It may also be desirable to use a mixture of aryl-alkenes in the preparation of the binder to impart desirable physical properties. For example, properties such as formulation miscibility, binder viscosity and binder molar refractive index can be tailored for the application at hand.

The diffusible binders of the present invention can alternatively be prepared by hydrolysis reaction of an aryldichloromethylsilane or an arylalkyldichloromethylsilane. The hydrolysis tends to give a thermodynamic mixture of both linear and cyclic products, and such mixtures used in formulations of holographic recording media showed improved robustness by comparison to use of Dow Corning® 710 and 705 silicone fluids.

A binder used in the process and preparation of the present medium of this invention preferably does not inhibit cationic polymerization of the monomers used (e.g., “supports” cationic polymerization), is miscible with the monomers used, is miscible with the polymerized structure formed, and has a refractive index that is significantly different from that of the polymerized monomer or oligomer (e.g., the refractive index of the binder differs from the refractive index of the polymerized monomer by at least 0.04 and preferably at least 0.09). Binders in this embodiment are required to increase cohesion in said medium, as is generally the case, and are preferably “diffusible”. Diffusible binders can, by way of example, segregate from the polymerizing monomer(s) or oligomer(s) during holographic recording via diffusion-type motion of the binder component. In general, binders can be inert to the polymerization processes described herein or optionally can polymerize (by cationic, free radical or other suitable polymerization) during one or more polymerization events. Preferably, a binder is inert to the polymerization processes defined herein and, even more preferably, is diffusible.

Preferred monomers for use in the present invention are siloxanes with epoxy functional groups and which are compounds that are generally stable on prolonged storage but capable of undergoing rapid cationic polymerization. For examples see U.S. Pat. No. 6,784,300 and EP 1 317 498 B1, the teachings of which are incorporated herein.

The acid generator used in the recording medium of the present invention produces an acid upon exposure to the actinic radiation. The term “acid generator” or PAG is used herein to refer to the component or components of the medium that are responsible for the radiation-induced formation of acid. Thus, the acid generator may comprise only a single compound that produces acid directly. Alternatively, the acid generator may comprise an acid generating component which generates acid and one or more sensitizers which render the acid generating component sensitive to a particular wavelength of actinic radiation, as discussed in more detail below. The acid produced from the acid generator may be either a Bronstead acid or Lewis acid, provided of course that the acid is of a type and strength which will induce cationic polymerization of the monomer. When the acid produces a Bronstead acid, this acid preferably has a pKₐ less than about 0. Known superacid precursors such as diazonium, sulfonium, phosphonium and iodonium salts may be used in the present medium, but iodonium salts are generally preferred. Diaryliodonium salts have been found to perform well in the present media, with specific preferred diaryliodonium salts being (5-octyloxyphenyl)phenyliodonium hexafluoroantimonate and ditolyliodonium tetrakis(pentafluorophenyl)borate.

In the absence of any sensitizer, iodonium salts are typically only sensitive to radiation in the far ultra-violet region, below about 300 nm, and the use of far ultra-violet radiation is currently inconvenient for the production of holograms because for a given level of performance ultra-violet lasers are substantially more expensive than visible lasers. It is well known, however, that by the addition of various sensitizers, iodonium salts can be made sensitive to various wavelengths of actinic radiation to which the salts are not substantially sensitive in the absence of the sensitizer. In particular, iodonium salts can be sensitized to visible radiation using certain aromatic hydrocarbons, a specific preferred sensitizer of this type being 5,12-bis(phenylethynyl)naphthacene or alternatively rubrene or, by way of example, those sensitizers described in WO 2004/059389 A2, the teachings of which are incorporated herein, which additionally are sensitizers for sulfonium salts. The aforementioned sensitizers render iodonium salts sensitive to visible actinic radiation such as, but not limited to the 514.5 and 488 nm radiation from an argon ion laser, and to the 532 nm radiation from a diode pumped frequency-doubled YAG laser (for the case of crystals comprising VO₄, wavelengths are generally somewhat shorter being between about 524 and 532 nm), both of which are convenient sources for the production of holograms. Preferably, the sensitizer is photobleachable so that the visible absorption of the holographic medium substantially decreases during exposure.

The proportions of acid generator, sensitizer, binder and monomers in the holographic recording medium of the present invention may vary rather widely, and the optimum proportions for specific components and methods of use can readily be determined empirically by skilled workers. Guidance in selecting suitable proportions is provided in U.S. Pat. No. 5,759,721 and 6,784,300, the teachings of which are incorporated herein by reference. In general, however, it is preferred that the present medium comprise from about 0.25 to about 5 parts by weight of the monofunctional or difunctional epoxide per part by weight of the polyfunctional epoxide monomer which preferably has an epoxy equivalent weight greater than about 300 (g/mole epoxy). The solution of monomers with the binder of the present invention can comprise a wide range of compositional ratios, preferably ranging from about 90 parts binder and 10 parts monomer or oligomer (w/w) to about 10 parts binder and 90 parts monomer or oligomer (w/w). It is preferred that the medium comprise from about 0.167 to about 5 parts by weight of the binder per total weight of the monomers.

Holographic Recording Media Comprising the Binder of the Present Invention

In on embodiment, the present invention is a A polymerizable media, comprising: a photo acid generator compound (PAG) which produces acid when exposed to actinic radiation; a dye which sensitizes the PAG to produce acid in response to a particular wavelength of light; at least one monomer or oligomer which is capable of undergoing cationic polymerization initiated by the acid produced by PAG when exposed to actinic radiation; and any of the binders of the present invention described above.

Preferably, the binders are selected so that, following exposure of the media to actinic radiation and subsequent polymerization of the monomers or oligomers, chemical segregation and spatial separation of the binder from a polymer formed from the monomer or oligomer produces refractive index modulation within the holographic recording media. In this embodiment, the polymerizable media can be employed as a holographic recording medium.

Any one or more, including mixtures, of the binders of the present invention can be used in polimerizable and holographic recording media of the present invention.

Preferably, the polymerizable and holographic recording media of the present invention has the molar refractive index of the binder is greater than 1.55. In one embodiment, at least one monomer of oligomer is an epoxide monomer or oligomer capable of undergoing cationic polymerization initiated by the acid produced by PAG. Preferably, at least one epoxide monomer or oligomer is a polyfunctional epoxide monomer or oligomer. For example, at least one epoxide monomer or oligomer comprises a cycloalkene oxide.

It is preferred, that at least one polyfunctional epoxide monomer or oligomer comprise a siloxane that has an epoxy equivalent weight of greater than about 300 g/mole epoxy.

Typically, the monomers and oligomers of the recording materials comprising the binders of this invention are siloxanes with epoxy functional groups. The preferred type of epoxy group is a cycloalkene oxide group, especially a cyclohexene oxide group. A “polyfunctional” monomer or oligomer is defined herein as a compound having at least three groups of the specified functionality, in the present case at least three epoxy groups. The terms “polyfunctional” and “multifunctional” are used interchangeably herein. A “difunctional” monomer or oligomer is a compound having two groups of the specified functionality; and a “monofunctional” monomer or oligomer is a compound having one group of the specified functionality.

Suitable monomers and oligomers are described, for example, in U.S. Pat. No. 5,759,721, U.S. Pat. No. 6,489,065, U.S. Pat. No. 6,784,300, U.S. Pat. No. 7,070,886, and U.S. patent application Ser. No. 11/385,979. The entire teachings of these patents and applications are incorporated herein by reference.

Preferably, monomers or oligomers is an epoxide monomer or oligomer capable of undergoing cationic polymerization initiated by the acid produced by PAG. More preferably, monomers or oligomers are polyfunctional epoxide monomers or oligomers. Even more preferably, the epoxide monomers or oligomers comprises a cycloalkene oxide. Yet more preferably, at least one polyfunctional epoxide monomer or oligomer comprises a siloxane that has an epoxy equivalent weight of greater than about 300 g/mole epoxy.

Generally, monomers or oligomers suitable for use with the present invention are represented by structural formula (XXX): 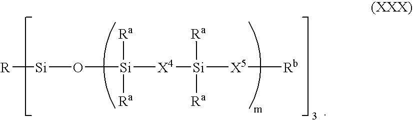
In formula (XXX), R is a substituted or unsubstituted aliphatic group, a substituted or unsubstituted aryl group or is a group represented by the following structural formulas:

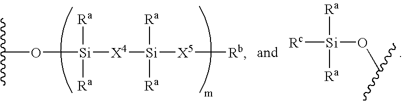

In another embodiment, monomers or oligomers suitable for use with the present invention are represented by structural formula (XXXII):

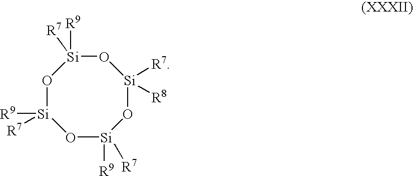

In formulas (XXX) and (XXXII):

X⁴ and X⁵ are each independently each R^{Z} is independently an optionally substituted C1-C12 alkyl group, optionally substituted C3-C12 cycloalkyl alkyl group, or an aryl optionally substituted with a C1-C12 alkyl, C1C12 alkene or C1-C12 alkyne group, a C1-C12 haloalkyl, a halogen, hydroxyl, a C1-C12 alkoxy group, optionally substituted aryloxy group or optionally substituted diaryl amino group;

each Y₁ is independently a covalent bond, or an optionally substituted C1-C12 alkylene group or optionally substituted C3-C12 cycloalkylene or an optionally substituted arylene group or optionally substituted C1-C 12 arylalkylene;

each R^{a} is, independently, a substituted or unsubstituted aliphatic group or a substituted or unsubstituted aryl group;

each R^{b} is an aliphatic group substituted with an epoxide;

R^{c} is H, an unsubstituted aliphatic group, a substituted aliphatic group, an unsubstituted aryl group, a substituted aryl group, a substituted siloxane group, an unsubstituted siloxane group, a substituted polysiloxane group or an unsubstituted polysiloxane group;

each group R⁷ is independently an unsubstituted aliphatic group, a substituted aliphatic group, an unsubstituted aryl group or a substituted aryl group;

each group R⁸ is R⁹, hydrogen, an alkenyl, a substituted or unsubstituted C1-C12 alkyl, C1-C12 cycloalkyl, aryl substituted C1-C12 alkyl or aryl or R^{Z}—(O—Y₁)ᵣ₋, (R^{Z})3—Si—(O—Si(R^{Z})₂)ₛ—Y₁₋, or (R^{Z})₃Si—(O—Si(R^{Z})₂)ₛ—O—;

each R₉ is independently represented by the following structural formula:

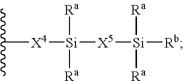

m is 1,2,3 or 4;

r is an integer from 1 to 10; and

s is 0 or an integer from 1 to 8.

Examples of suitable monomers and oligomers include the compounds represented by the following structural formulas: 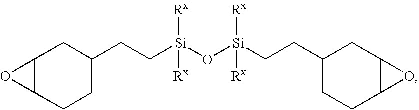
where Rx is a C1-C6 alkyl, preferably methyl;

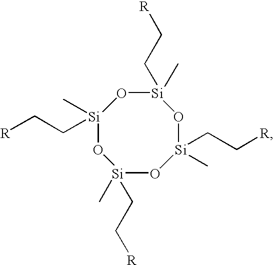

where R is represented by the following formula: 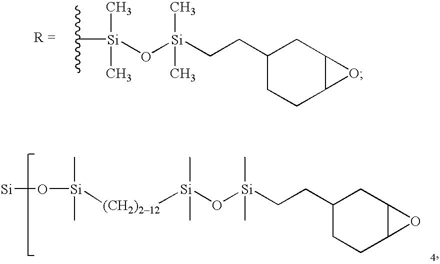
for example: 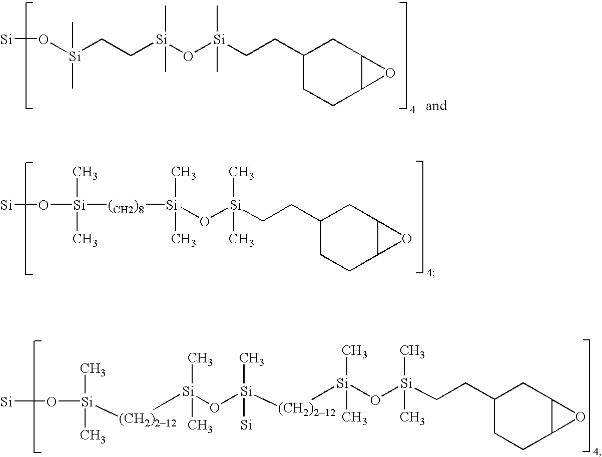
for example:

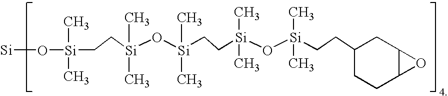

In another embodiment, the present invention is a method of recording holograms within a holographic recording media of the present invention. The method comprises the step of passing into the medium a reference beam of coherent actinic radiation to which the compound which produces acid when exposed to actinic radiation is sensitive and object beam of the same coherent actinic radiation, thereby forming within the medium an interference pattern and thereby recording a hologram within the medium.

### EXEMPLIFICATION

The following examples are now given, though by way of illustration only, to show details of particularly preferred binders and monomers, and the conditions and techniques used in preferred media of the present invention.

### Example 1A

Binder of the present invention using a cyclic tetramer fully substituted with an arylalkene to yield an arylalkyl-cyclotetrasiloxane.

### 2,4,6,8-Tetrakis[3-(1-naphthyl)propyl]-2,4,6,8-tetramethylcyclotetrasiloxane

| | MW | | | | |
|---|---|---|---|---|---|
| 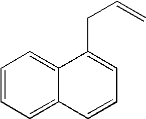 | 168.23 | 8.4 | g | (50 mmol) | |
| 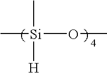 | 240.51 | 2.4 | g | (10 mmol) | Gelest SIT7530.0 Lot 3D-2839 1,3,5,7-Tetramethylcyclotetrasiloxane (TMCTS, D^{H}₄) n_{D}²⁰ = 1.3873 |
| Pt(Ø₃P)₄ | 1244.27 | 140 | μl | (TPPP) | Aldrich 24,496-1, solution of 4 mg TPPP/ml m-xylene |

(1.1 X 10⁻⁵ mol
Pt/mol SiH)

In a 50-ml 3NRB flask equipped with an oil bath, magnetic stirrer, thermometer, and 25-ml addition funnel connected to a nitrogen bubbler was added 1,3,5,7-tetramethylcyclotetrasiloxane (2.4 g, 99.5 area % by GC, IR spectrum shows SiH at 2171 cm⁻¹). 1-Allylnaphthalene (8.4 g) was then added to the addition funnel. After the flask was purged with nitrogen and heated in an oil bath at ˜70° C., the TPPP catalyst solution (140 μl) was added to the neat silane followed by drop-wise addition of 1-allylnaphthalene. The addition was completed in ˜20 minutes, and the bath temperature was then slowly increased to 110° C. to bring the pot temperature to 100° C., and stirring was continued under nitrogen overnight. TLC analysis (K5F silica) shows only allylnaphthalene at R_{f}=0.60, product at R_{f}=0.33, a very weak spot at R_{f}=0.22, and a spot at the origin. An IR spectrum confirms complete reaction with no presence of SiH peaks in the 2100-2200 cm⁻¹ region.

Volatiles were removed with a nitrogen sparge in an oil bath at ˜110° C. Next the viscous oil was mixed with hexanes (˜50 ml) to form a cloudy mixture. The mixture was treated with silica gel (Baker 7024, 40μ Flash Chromatography Packing,) 2.0 g After stirring overnight the mixture was filtered, via vacuum filtration, to yield a clear colorless solution. Hexane was removed by distillation followed by a nitrogen sparge at 120° C. to remove trace volatiles.

The yield of clear, colorless oil, highly viscous at room temperature, was 8.245 g (90%); n_{D}²⁰=1.6016 (z=30.5). TLC analysis was consistent with pure product.

GPC analysis on this sample showed a principle narrow peak at 9.349 min. retention time (98.5 area %) and a small peak at 8.924 min. retention time due to a small amount (1.5%) of the cyclic pentamer.
Binder of Example 1A

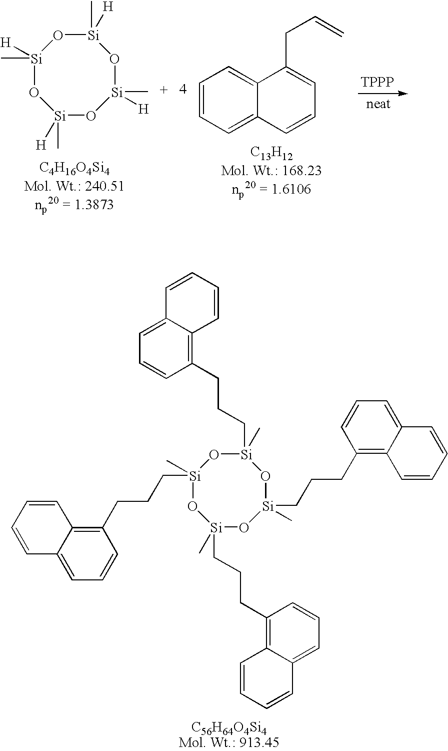

### Example 1b

Following the above outlined procedure a cyclic binder of the present invention was prepared using 1,3,5,7,9-pentamethylcyclopentasiloxane in place of 1,3,5,7-tetramethylcyclotetrasiloxane, and 5% Pt on Carbon in place of the tetrakis triphenylphosphine platinum catalyst. The resultant material, a cyclopentasiloxane, shown as Structural Formula (VIIb) was a clear colorless viscous oil with a refractive index n_{D}²⁰=1.6010 (z=30).

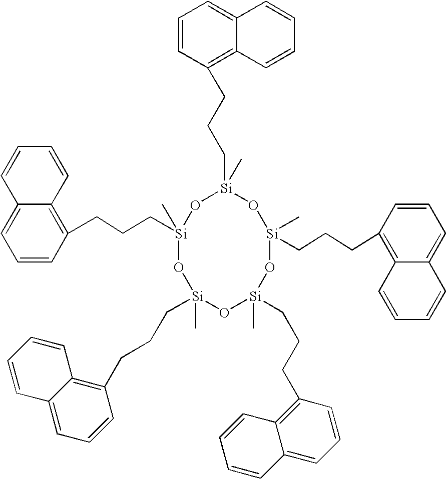

### Example 1C

Following the above outlined procedure a binder of the present invention was prepared using 1-isopropenylnaphthalene in place of 1-allylnaphthalene and 5% Pt on Carbon in place of the tetrakis triphenylphosphine platinum catalyst. The resultant material, a cyclotetrasiloxane, shown as Structural Formula (VIII) was a clear colorless viscous oil with a refractive index of 1.6070, z=30.5

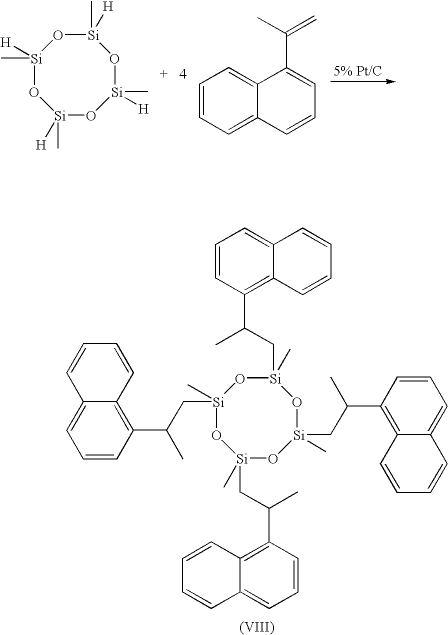

### Example 2A

Binders of the present invention comprising a mixture of cyclicmethylsiloxane rings substituted with a mixture of arylalkenes to yield an arylalkylcyclomethylsiloxane with a mixture of arylalkyl substituents (see illustrative example Structural Formula (IX) below).

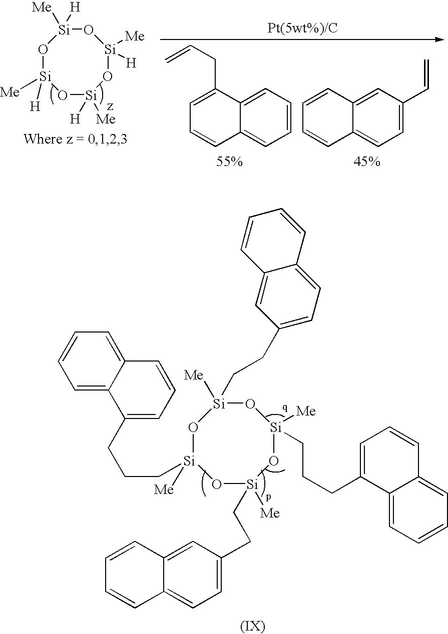

In a 50-ml 3NRB flask equipped with an oil bath, magnetic stirrer, thermometer, and 25-ml addition funnel connected to a nitrogen bubbler was added MH1109 a cyclomethylsiloxane from Dow Coming Corporation (mixture of tetra, penta and hexacyclic material as determined by GPC, IR spectrum shows SiH at 2171 cm⁻¹) and 40 mg of Pt/C (5% Pt content). Whilst stirring the reaction vessel was heated to ˜75° C. A solution composed of 1-Allylnaphthalene (7.00 g) and 2-vinylnaphthalene (6.42 g) was charged to an addition funnel was then added in small increments to the reaction vessel. After the first 20% ˜2 grams the oil bath temperature was raised to 100° C., the reaction temperature was measured at 95° C. A second aliquot of naphthalene mixture was added and a slight exothermic event was noted. The remaining solution was added over the ˜30 minutes while the oil bath temperature was raised to ˜120° C. After three hours at ˜120° C. some Si—H remains unconverted as indicated by Infrared analysis. An additional 1.0 g of 1-allylnaphthalene was added to the reaction mixture and stirring continued for 3 more hours. Infrared analysis and TLC indicate complete reaction.

The reaction was worked-up as described for Example 1using proportionally more hexanes and silica gel to yield a clear and colorless viscous oil with a refractive index of 1.6082 with a z=31.0.

Further following the above outlined procedure, a series of “binders” of the present invention were prepared with the following general structure shown as Structural Formula (X).

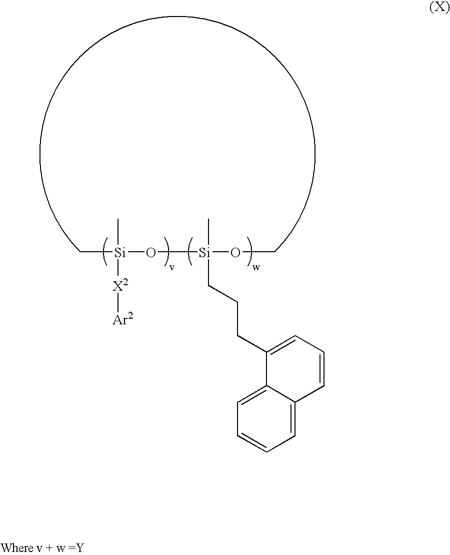

wherein n and m are the normalized mole equivalents used in the reaction feed and Y is the number of repeat units in the cyclicmethylsiloxane. Various binders of the present invention of this type are listed as illustrative examples in the table below for different Ar groupings, n/m rations and values of Y, along with the corresponding data for refractive index, n_{D}²⁰.

| | | | | | Struc- |
|---|---|---|---|---|---|
| | | | | | tural |
| Ar— | —X— | n/m | n_{D}²⁰ | Y | Formula |
| 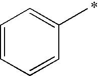 | —(CH₂CH₂)— | ˜0.26 | 1.5905 | 4, 5, 6 | (Xa) |
| 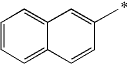 | —(CH₂CH₂)— | 1 | 1.6082 | 4, 5, 6 | (IX) |
| 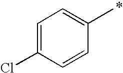 | —(CH₂CH₂)— | ˜0.25 | 1.5945 | 4, 5, 6 | (Xb) |
| 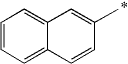 | —(CH₂CH₂)— | 1 | 1.6080 | 4 | (Xc) |
| 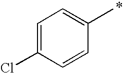 | —(CH₂CH₂)— | 0.25 | 1.5945 | 5 | (Xd) |

### Example 3

### Binder for Comparative Purposes Using the Alternative Star Morphology

### TETRAKIS[3-(1-NAPHTHYL)PROPYLDIMETHYLSILOXY]SILANE

| | MW | g/ml | | | | |
|---|---|---|---|---|---|---|
| 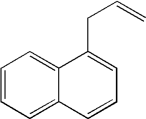 | 168.23 | | 8.4 | g | (50 mmol) | |
| 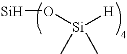 | 328.73 | 0.886 | 3.3 | g | (10 mmol) | UCT T1915 Lot #20200098 bp 190° C. n_{D}²⁰ =1.3841 |
| Pt(Ø₃P)₄ | 1244.27 | | 140 | μl | (TPPP) | Aldrich 24,496-1, solution of 4 mg TPPP/ml m-xylene |

(1.1 X 10⁻⁵ mol
Pt/mol SiH)

In a 50-ml 3NRB flask equipped with an oil bath, magnetic stirrer, thermometer, and 25-ml addition funnel connected to a nitrogen bubbler was added tetrakis(dimethylsiloxy)silane (3.3 g, 97.8 area % by GC, IR spectrum shows SiH at 2136 cm⁻¹). 1-Allylnaphthalene (8.4 g) was then added to the addition funnel. After the flask was purged with nitrogen and heated in an oil bath at ˜60° C., the TPPP catalyst solution (140 μl) was added to the neat silane followed by dropwise addition of 1-allylnaphthalene. The addition was completed in ˜45 min to give a clear light-yellow viscous liquid. The bath temperature was increased to 110° C. to bring the pot temperature to 100° C., and stirring was continued under nitrogen overnight.

An IR spectrum of a sample taken the next day shows that the SiH peak is extremely weak or absent. A fairly weak peak in the IR spectrum at 1639 cm^{-l} is due to the C═C stretching band and is assigned to the presence of excess allylnaphthalene.

TLC analysis is indicative of complete reaction with the product having an R_{f}=0.37 (20% MeCl2 in hexanes).

The product oil was dissolved in hexanes (˜100 ml, miscible at room temperature) and stirred with activated carbon (˜1 g) for ˜4 hours. It was then filtered through a bed of packed Celite in a sintered glass funnel and the solids were washed thoroughly with hexanes (˜50 ml). The filtrate was concentrated, removing hexanes by distillation and the excess allylnaphthalene was evaporated in a stream of nitrogen at a solution temperature of ˜20° C.

Following the removal of the excess allynaphthalene the resultant light yellow oil was further purified by Flash Column Chromatography. This was accomplished by using hexanes as the eluent and silica gel (Baker 7024, 40μ Flash Chromatography Packing) as the solid phase with a nitrogen pressure (˜5 psi). The column was eluted with an additional ˜150 ml hexanes, and the clear solution was distilled in a 250-ml 1NRB flask to recover the hexanes

The product was re-constituted by distilling off hexanes followed by a nitrogen sweep in an oil bath at ˜135° C . The flask was then carefully evacuated with continued stirring at ˜135° to a pressure of <70 mTorr. After ˜2 hours, the bath temperature was reduced to 100° C., and stirring was continued overnight under high vacuum.

The product oil (TNPSS Star Binder shown as Structural Formula (XI)) is clear and colorless; Yield: 9.145 g (91.3%); n_{D}²⁰=1.5768 (z =28.5). The viscosity of the neat tetrakis[3-(1-naphthyl)propyl-dimethylsiloxy]silane (Brookfield LVDV-II+CP cone and plate viscometer with the CPE-51 cone) was 1880 cP at 25.1° C. For reference, the value for Dow Corning 710 fluid (polymethylphenylsiloxane) was 533.9 cP at 25.1° C.

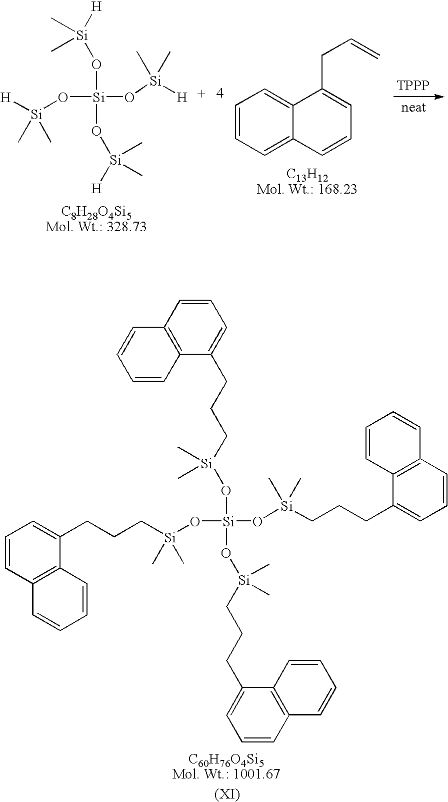

### Example 4

Preparation of a Holographic Recording Medium with Binders of the Present Invention

A binder of the present invention was charged to vessel equipped with a magnetic stir bar. To the binder was added a difunctional epoxide monomer represented by Structural formula (XII):
R′—Si(RR)—O—Si(RR)—R′

### (XII)

wherein each group R′ is a 2-(3,4-epoxycyclohexyl)ethyl grouping; and each grouping R is a methyl group, and which is available from Polyset Corporation, Inc., Mechanicsville, N.Y., under the trade name PC-1000. The ratio of the binder to the di-functional monomer was 1.:46: 1.0. The mixture of binder and di-functional monomer was stirred to form a uniform homogeneous mixture. To this mixture was added a poly-functional monomer, referred to herein as C8 tetramer (see U.S. Pat. No. 6,784,300, incorporated herein by reference in its entirety, compound No. XXII), in a ratio of 1.12:1 multifunctional epoxy to difunctional monomer, and the contents were stirred at room temperature to form a uniform mixture. Sensitizer (rubrene) was added to the uniform mixture of the binder and monomers resulting in a desirable optical density at a concentration of about 0.035% by weight of the final recording medium. The mixture was stirred and heated to 60° C. to dissolve the sensitizer. When the sensitizer was completely dissolved the homogeneous mixture was allowed to cool to room temperature. To this mixture was added 6% by weight of the final recording medium of cumyltolyliodonium tetrakis(pentafluorophenyl)borate. The mixture was rapidly stirred until the PAG dissolved. Next the formulation was filtered using an Acrodisc® CR25 mm Syringe filter with a 0.2 micron PTFE Membrane into an appropriate size storage container.

A card type media was prepared by first fixing two flat glass substrates disposed in a parallel, coplanar arrangement with a space or gap of ˜300 microns between the inner surfaces of the top and bottom substrates. Examples of methods for media assembly can be found in U.S. Pat. No. 6,881,464, the entire teachings of which are incorporated herein. The formulation was coated between the two substrates using capillary forces. After complete filling of the “gap” the media was ready for further analysis.

### Example 5

Accelerated Aging of Holographic Media Prepared with Binders of the Present Invention

A series of holographic formulations were prepared using binders of the present invention. For comparison purposes an additional holographic formulation was prepared using a binder of the prior art, Dow Coming® 705. Each formulation and subsequent holographic medium was prepared according to the procedure outline in Example 4. After preparation the media was fully exposed to substantially effect a fully recorded state. The medium were subsequently placed in an oven at 73° C. to achieve accelerated aging conditions. The media were removed periodically and examined for the presence of physical, mechanical, optical or other such defects. Such observable defects, by way of example, are (1) Cracking, defined herein as a separation in the continuity of the formulation sandwiched between the substrates and which could range in type and size from a hairline crack to a large fissure, (2) Delamination, defined herein as a separation of the substrate from the cured or partially cured formulation, and (3) Exudation, defined herein as the migration of the mobile component out of the cured formulation to the peripheral edge and/or interfacial surface of the media and substrates.

### Example 5A

### Media of the Prior Art Using Dow Coming 705 as the Mobile Component

Media prepared using Dow Coming 705 as the binder was fully exposed using visible light. The media of this example were placed in an oven previously set and isothermally held at 73° C. ±1° C.

Within 3 hours all examples of this media exhibited at least one of the failure defects described above. Typically the media would first show signs of exudation followed by the formation of hairline cracks increasing in size or in quantity and then delamination would occur due to massive exudation of the mobile phase form the cured formulation.

### Comparative Example 5B

Media of the Present Invention was Prepared as Outline in Example 4 Using a Binder of Structural Formula (IX) or (Xa)-(Xd)

A series of media prepared using the binders of Structural Formula (IX), (Xa), (Xb), (Xc) and (Xd) of the present invention were fully exposed using visible light. The various pieces of media for this comparative example were placed in an oven previously set and isothermally held at 73° C. ±1° C. After 3 hours there was no evidence of delamination or cracking or of binder exudation. After 30 hours there was no evidence of delamination or cracking or of binder exudation. After 300 hours at 73° C. ±1° C. there was no evidence of delamination or cracking or of binder exudation.

### Comparative Example 5C

Media of the Present Invention was Prepared as Outline in Example 4 Using a Binder of Structural Formula XI

Media prepared using the binder XI of the present invention were fully exposed using visible light as described above. The various pieces of media for this comparative example were placed in an oven previously set and isothermally held to 73° C. ±1° C. After 3 hours there was no evidence of delamination or cracking or binder exudation. After 30 hours there was no evidence of delamination or cracking or binder exudation. The media using Binder XI started to exhibit delamination after being held for greater than 30 hours at 73° C. ±1° C. but for less than 48 hours.

### Example 6

### Bulk Light Scattering Using Binders in a Holographic Media

A series of holographic formulations were prepared using binders of the present invention. For comparison purposes an additional holographic formulation was prepared using a binder of the prior art, Dow Coming® 705. Each formulation was prepared according to the procedure described in Example 4. Each formulation was then used in the preparation of 50 mm×50 mm card type media with a gap of 400 microns between the inner surfaces of the substrates.

Next the media was light conditioned using a Xe strobe lamp, where the bulb comprised a UV cut-off filter to limit the exposure to the visible spectrum. Following the conditioning process the media was further exposed to a white light source to fully bleach the media. After such exposure conditions the media was examined using light scatter measurements as described further below.

Forward scattering measurement were made with a customized Scatterometer comprising a HeNe laser and an integrating sphere and A/D electronics. The sample was mounted directly in front of the integrating sphere and oriented normal to the laser beam. Measurements were taken by scanning at 1 mm intervals in the y-direction (horizontally) at three different z-direction (vertical) locations. The average of the acquired data was used to compare light scattering performance of the polymerized media. A background reading for air was obtained to use for normalizing the scatter data by subtraction of the background signal from the average scatter data of the media. The results of the scatter measurements are given in the accompanying figure below for media made with binders of this invention compared to media made with Dow Corning® 705 as the binder. The plot shows the digitized average forward light scattering for each media sample normalized to account for background light scattering from air.

The results show that greater than 50% reduction in forward light scattering is advantageously achieved using binders of the present invention in a formulation for a holographic recording material as compared to binders of the prior art. Reduced scatter is advantageous for scatter contributes to noise and therefore impairs the fidelity of a recorded data page hologram, and, additionally, scatter reduces achievable data density, D, due to its dependence of D ∝1/ε_{scatter}^{0.5} where ε_{scatter} is the scatter per steradian into the direction of the detector (see Applied Optics, Vol. 43, No. 25, 2004, pp 4902-4914).

While this invention has been particularly shown and described with references to example embodiments thereof, it will be understood by those skilled in the art that various changes in form and details may be made therein without departing from the scope of the invention encompassed by the appended claims.

What is claimed is:

1. A compound represented by structural formula (XII): 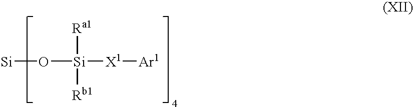
wherein:
X¹, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁—[O—Y₁]ₛ₋, —Y₁—Si(R^{Z})₂—Y₁₋, —Y₁—Si(R^{Z})₂—Y₁—O—Y₁—Si(R^{Z})₂—Y₁₋, or —Y₁—Si(R^{Z})₂—Y₁ —Si(R^{Z})₂—Y₁₋;
R^{a1} and R^{b1}, for each occurrence, are independently an optionally substituted C1-C12 alkyl or optionally substituted C3-C12 cycloalkyl or an optionally substituted aryl or an optionally substituted heteroaryl;
Ar¹, for each occurrence, is independently an optionally substituted aryl or an optionally substituted heteroaryl;
each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;
each Y₁ is independently a covalent bond, or an optionally substituted C1-C12 alkylene group or optionally substituted C3-C12 cycloalkylene or an optionally substituted arylene group or optionally substituted C1-C12 arylalkylene; and
s is 0 or an integer from 1 to 8.

2. A compound of claim 1, wherein the refractive index of said compound is equal to or greater than 1.550.

3. A compound of claim 1, wherein the viscosity of said compound is greater than 175 centistokes.

4. A compound of claim 1, wherein at least one group —X¹-Ar¹ is different from the other —X¹-Ar¹ groups in formula (XII).

5. A compound of claim 4, wherein at least one Ar¹ group is different from the other Ar¹ groups in structural formula (XII).

6. The compound of claim 4, represented by structural formula (XX): 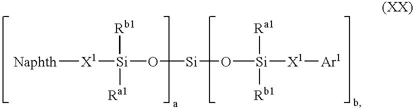
wherein Naphth is naphthyl, optionally substituted with halogen, hydroxyl, C1-C12 alkyl, C2-C12 alkene or C2-C12 alkyne, C3-C12 cycloalkyl, C1-C12 haloalkyl, optionally substituted C1-C12 alkoxy, optionally substituted aryloxy, optionally substituted arylamino or optionally substituted aryl group and a and b are, independently, positive integers from 1 to 3, such that a+b=4.

7. A compound of claim 6, wherein X¹, for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋.

8. The compound of claim 7, wherein Y₁ is an optionally substituted C1-C12 alkylene or optionally substituted C1-C12 arylalkylene, and R^{Z} is independently an optionally substituted C1-C12 alkyl group, optionally substituted C3-C12 cycloalkyl group, or an aryl optionally substituted with a C1-C12 alkyl, C1-C12 alkene or C1-C12 alkyne group, a C1-C12 haloalkyl, a halogen, hydroxyl, optionally substituted C1-C12 alkoxy group, optionally substituted aryloxy group or optionally substituted diaryl amino group.

9. The compound of claim 8, wherein Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, C1-C12 alkene or C1-C12 alkyne group, C1-C12 alkoxy, optionally substituted aryloxy, C1-C12 haloalkyl or optionally substituted arylamino.

10. The compound of claim 9, wherein R^{a1} and R^{b1}, for each occurrence, are independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl

11. The compound of claim 10, wherein X¹ is —(CHR′)ₙ₋, wherein
n is from 1 to 12;
R′, for each occurrence, is independently:
(i) a hydrogen; or
(ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or
(iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, arylamino group and C1-C12 haloalkyl.

12. The compound of claim 11, represented by structural formula (XXII): 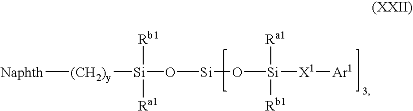
wherein y is a positive integer from 2 to 6.

13. The compound of claim 12, wherein Ar¹ for each occurrence, is independently

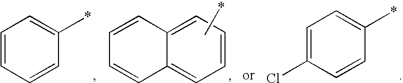

14. The compound of claim 13, wherein X¹ is —(CH₂)₂₋ or —(CH₂)₃₋; y is 2 or 3; and R^{a1} and R^{b1}, for each occurrence, are independently a C1-C12 alkyl or a phenyl, optionally substituted with halogen, hydroxyl, C1-C12 alkyl, C2-C12 alkeneyl or C2-C12 alkynyl group, C1-C12 alkoxy, optionally substituted aryloxy group, optionally substituted arylamino group and C1-C12 haloalkyl.

15. The compound of claim 1, wherein X¹, for each occurrence, is independently an optionally substituted C1-C12 alkylene, an optionally substituted C3-C12 cycloalkylene, an optionally substituted C1-C12 arylalkylene, an optionally substituted arylene, —Y₁—Si(R^{Z})₂—Y₁₋.

16. The compound of claim 15, wherein Y₁ is an optionally substituted C1-C12 alkylene or optionally substituted C1-C12 arylalkylene, and R^{Z} is independently an optionally substituted C1-C12 alkyl group, optionally substituted C3-C12 cycloalkyl group, or an aryl optionally substituted with a C1-C12 alkyl, alkene or alkyne group, a C1-C12 haloalkyl, a halogen, hydroxyl, a C1-C12 alkoxy group, optionally substituted aryloxy group or optionally substituted diaryl amino group.

17. The compound of claim 16, wherein Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, alkene or alkyne group, C1-C12 alkoxy, optionally substituted aryloxy, C1-C12 haloalkyl or optionally substituted arylamino.

18. The compound of claim 17, wherein R^{a1} and R^{b1}, for each occurrence, are independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl.

19. The compound of claim 18, wherein X¹ is —(CHR′)ₙ₋, wherein
n is from 1 to 12;
R′, for each occurrence, is independently:
(i) a hydrogen; or
(ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or
(iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl.

20. The compound of claim 19, wherein Ar¹ for each occurrence, is independently

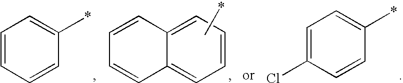

21. The compound of claim 20, X¹ is —(CH₂)₂₋ or —(CH₂)₃₋; y is 2 or 3; and R^{a1} and R^{b1}, for each occurrence, are C1-C12 alkyl or phenyl, optionally substituted with halogen, hydroxyl, C1-C12 alkyl, C2-C12 alkeneyl or C2-C12 alkynyl group, C1-C12 alkoxy, optionally substituted aryloxy group, optionally substituted arylamino group and C1-C12 haloalkyl.

22. The compound of claim 21 represented by structural formula (XI):

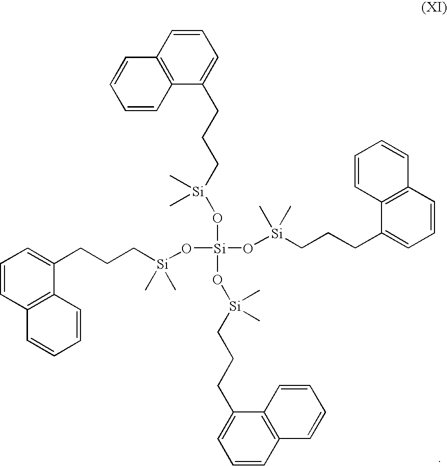

23. The compound of claim 2, wherein the Ar¹ is a substituted or unsubstituted aryl group or a substituted or unsubstituted heteroaryl group connected through an Si—O group to a central Si atom, or connected by a linker through an Si—O group to a central Si atom, wherein the Si atom in the SiO group is substituted with aliphatic group, aryl or a mixture of both groups.

24. The compound of claim 23, wherein the linker is an aliphatic grouping.

25. The compound of claim 24, wherein Ar¹ is a phenyl, naphthyl, phenanthryl, fluorenyl, or pyrenyl or mixture thereof when connected through an Si—O group to the central Si atom, or is an alkyl-naphthyl, alkyl-phenanthryl, alkyl-fluorenyl, or alkyl-pyrenyl or mixture thereof when connected by an aliphatic grouping through an Si—O group to a central Si atom.

26. A compound represented by structural formula (XV): 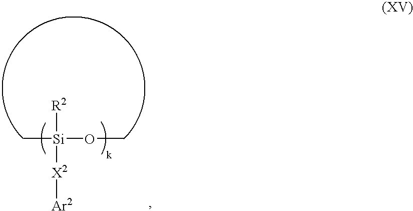
wherein:
R², for each occurrence, is independently an optionally substituted C1-C12 alkyl, an optionally substituted C3-C12 cycloalkyl, or an optionally substituted aryl;
X², for each occurrence, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁—[O—Y₁]ₛ₋, —Y₁ —Si(R^{Z})₂—Y₁₋, —Y₁—Si(R^{Z})₂—Y₁O—Y₁—Si(R^{Z})₂—Y₁₋, or —Y₁—Si(R^{Z})₂—Y₁ —Si(R^{Z})₂—Y₁₋;
Ar², for each occurrence, is independently an optionally substituted aryl or an optionally substituted heteroaryl;
each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;
each Y₁ is independently a covalent bond, or an optionally substituted C1-C12 alkylene group or optionally substituted C3-C12 cycloalkylene or an optionally substituted arylene group or optionally substituted C1-C12 arylalkylene;
k is an integer from 3 to 6; and
s is 0 or an integer from 1 to 8.

27. A compound of claim 26, wherein the refractive index of said compound is equal to or greater than 1.550.

28. A compound of claim 26, wherein the viscosity of said compound is equal to or greater than 175 centistokes.

29. A compound of claim 26, wherein at least one —X²-Ar² group is different from the other —X²-Ar² groups in formula (XV).

30. A compound of claim 29, wherein at least one Ar² group is different from the other Ar² groups in structural formula (XV).

31. A compound of claim 29, represented by structural formula (XVI): 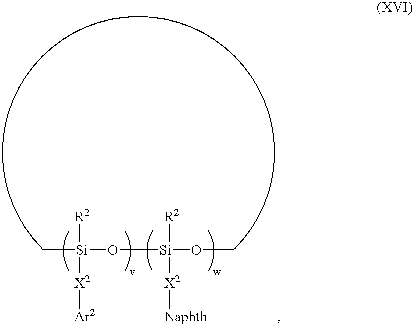
wherein Naphth is naphthyl, optionally substituted with halogen, hydroxyl, C1-C12 alkyl, alkene or alkyne, C3-C12 cycloalkyl, C1-C12 haloalkyl, C1-C12 alkoxy, optionally substituted aryloxy, optionally substituted arylamino or optionally substituted aryl group, and v and w are positive integers such that the sum of v and w is 3,4, 5 or 6.

32. A compound of claim 31, wherein X², for each occurrence, is independently an optionally substituted C1-C12 alkylene, an optionally substituted C3-C12 cycloalkylene, an optionally substituted C1-C12 arylalkylene, an optionally substituted arylene, —Y₁—Si(R^{Z})₂—Y₁₋.

33. The compound of claim 32, wherein Y₁ is an optionally substituted C1-C12 alkylene or optionally substituted C1-C12 arylalkylene, and R^{Z} is independently an optionally substituted C1-C12 alkyl group, optionally substituted C3-C12 cycloalkyl group, or an aryl optionally substituted with a C1-C12 alkyl, alkene or alkyne group, a C1-C12 haloalkyl, a halogen, hydroxyl, a C1-C12 alkoxy group, optionally substituted aryloxy group or optionally substituted diaryl amino group.

34. The compound of claim 33, wherein Ar² is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, alkene or alkyne group, C1-C12 alkoxy, optionally substituted aryloxy, C1-C12 haloalkyl or optionally substituted arylamino.

35. The compound of claim 34, wherein R², for each occurrence, for each occurrence, (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl.

36. The compound of claim 35, wherein X² is —(CHR′)ₙ₋, wherein
n is from 1 to 12;
R′, for each occurrence, is independently:
(i) a hydrogen; or
(ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or
(iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl.

37. The compound of claim 36, wherein Ar² for each occurrence, is independently

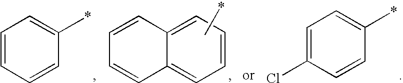

38. The compound of claim 37, represented by structural formula (XVII): 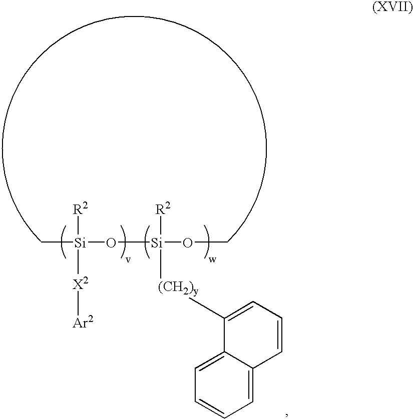
wherein y is a positive integer from 2 to 6.

39. The compound of claim 38, represented by structural formula (X): 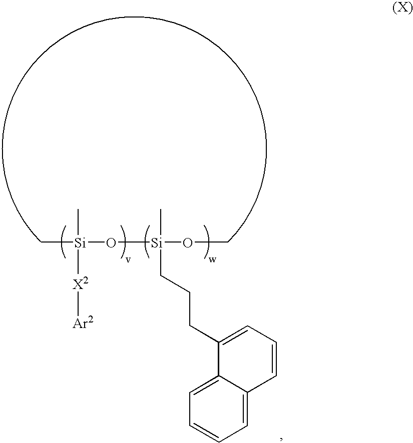
wherein X² is —(CH₂)₂₋ or —(CH₂)₃₋.

40. The compound of claim 39, wherein Ar² is phenyl or 2-naphthyl or 3-chlorophenyl.

41. A compound of claim 26, wherein X², for each occurrence, is independently an optionally substituted C1-C12 alkylene, an optionally substituted C3-C12 cycloalkylene, an optionally substituted C1-C12 arylalkylene, an optionally substituted arylene, or —Y₁—Si(R^{Z})₂—Y₁₋.

42. A compound of claim 41, wherein Y₁ is an optionally substituted C1-C12 alkylene or optionally substituted C1-C12 arylalkylene, and R^{Z} is independently an optionally substituted C1-C12 alkyl group, optionally substituted C3-C12 cycloalkyl group, or an aryl optionally substituted with a C1-C12 alkyl, alkene or alkyne group, a C1-C12 haloalkyl, a halogen, hydroxyl, a C1-C12 alkoxy group, optionally substituted aryloxy group or optionally substituted diaryl amino group.

43. The compound of claim 42, wherein Ar¹ is selected from phenyl, biphenyl, naphthyl, phenanthryl, anthracenyl, pyrenyl, fluoranthyl or fluorenyl, each optionally substituted with one or more substituents selected from halogen, hydroxyl, C1-C12 alkyl, alkene or alkyne group, C1-C12 alkoxy, optionally substituted aryloxy, C1-C12 haloalkyl or optionally substituted arylamino.

44. The compound of claim 43, wherein R², for each occurrence, is independently (i) C1-C12 alkyl or C3-C12 cycloalkyl, each optionally substituted by one or more halogen, hydroxyl, C1-C12 alkyl, C1-C12 alkoxy, and C1-C12 haloalkyl, or (ii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl

45. The compound of claim 44, wherein X² is —Y₁—Si(R^{Z})₂—Y₁₋, or —(CHR′)ₙ₋, wherein
n is from 1 to 12;
R′, for each occurrence, is independently:
(i) a hydrogen; or
(ii) C1-C12 alkyl or a C3-C12 cycloalkyl, each optionally substituted by one or more halogen, hydroxyl, C1-C12 alkyl, C2-C12 alkenyl or C2-C12 alkynyl group, C1-C12 alkoxy, or C1-C12 haloalkyl; or
(iii) a phenyl, optionally substituted with one or more halogen, hydroxyl, C1-C12 alkyl, C2-C12 alkenyl or C2-C12 alkynyl group, C1-C12 alkoxy, optionally substituted aryloxy group, optionally substituted arylamino group and C1-C12 haloalkyl

46. The compound of claim 45, wherein Ar² for each occurrence, is independently

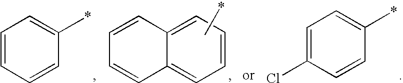

47. A compound of claim 46, represented by any of the following structural formulas:

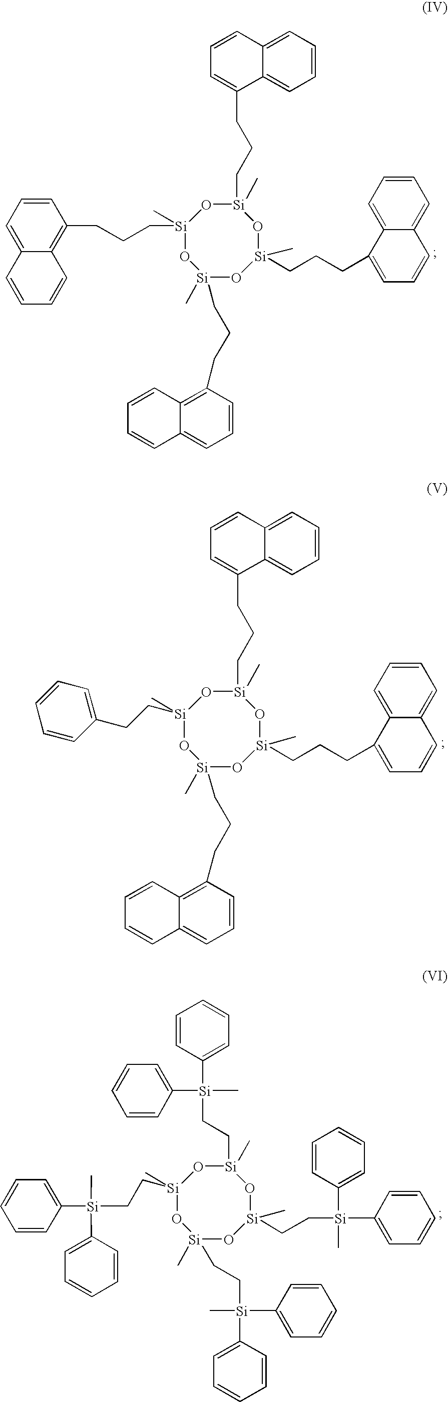

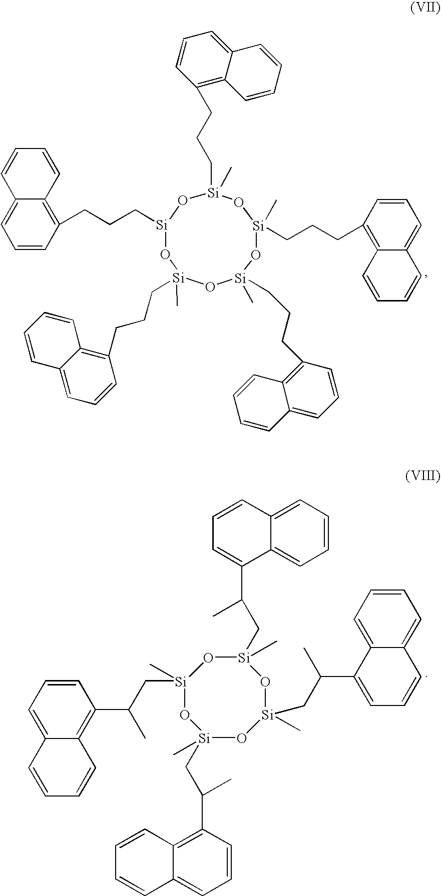

48. The compound of claim 46, represented by structural formula (IX): 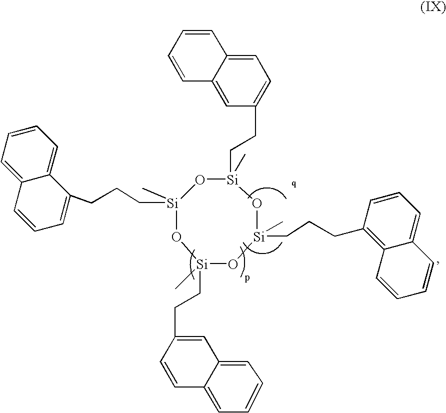
where in p+q=k−2.

49. A compound of claim 26, represented by structural formula (II): 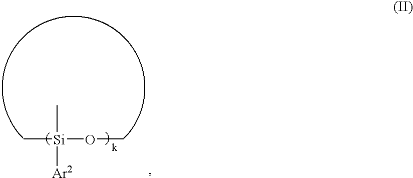
wherein k=3, 4, 5, or 6 and which has a molar refractive index greater than 1.55.

50. A compound of claim 26, represented by structural formula (III) 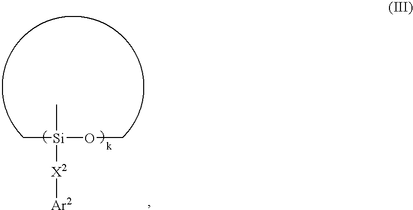
wherein X² is a covalent bond, or a moiety selected from an optionally substituted, an optionally substituted alkylene, an optionally substituted cycloalkylene, and an optionally substituted alkeneyl,
and further wherein said moiety optionally comprises a hetero atom selected form O and Si, wherein Si atom is substituted with one or more groups selected from an aliphatic group and an aryl, or a mixture of both groups.

51. A compound of claim 26, represented by structural formula (III): 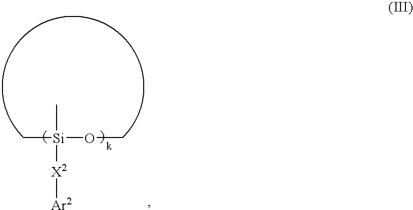
wherein k=3, 4, 5, or 6 and which has a molar refractive index greater than 1.55.

52. A compound according to claim 51 wherein the Ar² is an aromatic substituted or unsubstituted aryl group or a substituted or unsubstituted heteroaryl group connected to the Si of a repeat unit or is connected through a linker to the Si of a repeat unit wherein the linker group is an aliphatic grouping.

53. A compound according to claim 52 wherein the Ar² grouping is a phenyl, naphthyl, phenanthryl or mixture thereof, when connected to the Si of a repeat unit, or is an alkyl-naphthyl, or alkyl-phenanthryl, alkyl-fluorenyl, or alkyl-pyrenyl or mixture thereof when connected through a linker to the Si of a repeat unit wherein the linker group is an aliphatic grouping.

54. A polymerizable media, comprising:
a) a photo acid generator compound (PAG) which produces acid when exposed to actinic radiation;
b) a dye which sensitizes the PAG to produce acid in response to a particular wavelength of light;
c) at least one monomer or oligomer which is capable of undergoing cationic polymerization initiated by the acid produced by PAG when exposed to actinic radiation; and
d) any of the compounds of claims 1 through 53.

55. The polymerizable media of claim 54, wherein the at least one monomer or oligomer is represented by structural formulas (XXX) 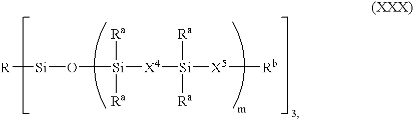
wherein R is a substituted or unsubstituted aliphatic group, a substituted or unsubstituted aryl group or is a group represented by the following structural formulas: 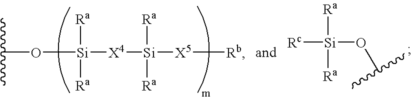
or structural formula (XXXII): 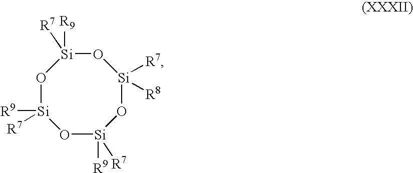
wherein:
X⁴ and X⁵ are each independently each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;
each Y₁ is independently a covalent bond, or an optionally substituted C1-C12 alkylene group or optionally substituted C3-C12 cycloalkylene or an optionally substituted arylene group or optionally substituted C1-C12 arylalkylene;
each R^{a} is, independently, a substituted or unsubstituted aliphatic group or a substituted or unsubstituted aryl group;
each R^{b} is an aliphatic group substituted with an epoxide;
R^{c} is H, an unsubstituted aliphatic group, a substituted aliphatic group, an unsubstituted aryl group, a substituted aryl group, a substituted siloxane group, an unsubstituted siloxane group, a substituted polysiloxane group or an unsubstituted polysiloxane group;
each group R⁷ is independently an unsubstituted aliphatic group, a substituted aliphatic group, an unsubstituted aryl group or a substituted aryl group;
each group R⁸ is R⁹, hydrogen, an alkenyl, a substituted or unsubstituted C1-C12 alkyl, C1-C12 cycloalkyl, aryl substituted C1-C12 alkyl or aryl or R^{Z}—(O—Y₁)ᵣ₋, (R^{Z})3—Si—(O—Si(R^{Z})2)ₛ—Y₁₋, or (R^{Z})₃Si—(O—Si(R^{Z})₂)ₛ—O—;
each R₉ is independently represented by the following structural formula: 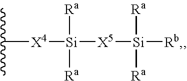
m is 1, 2, 3 or 4;
r is an integer from 1 to 10; and
s is 0 or an integer from 1 to 8.

56. A holographic recording media, comprising:
a) a photo acid generator compound (PAG) which produces acid when exposed to actinic radiation;
b) a dye which sensitizes the PAG to produce acid in response to a particular wavelength of light;
c) at least one monomer or oligomer which is capable of undergoing cationic polymerization initiated by the acid produced by PAG when exposed to actinic radiation; and
d) a binder of any of the compounds of claims 1 through 53, wherein chemical segregation and spatial separation of the binder from a polymer formed from the monomer or oligomer, produces refractive index modulation within the holographic recording media.

57. The holographic recording media of claim 56, wherein the molar refractive index of the binder is greater than 1.55.

58. The holographic recording media of claim 56, wherein the at least one monomer of oligomer is an epoxide monomer or oligomer capable of undergoing cationic polymerization initiated by the acid produced by PAG.

59. The holographic recording media of claim 58, wherein the at least one epoxide monomer or oligomer is a polyfunctional epoxide monomer or oligomer.

60. The holographic recording media of claim 59, wherein the at least one epoxide monomer or oligomer comprises a cycloalkene oxide.

61. The holographic recording media of claim 60, wherein the at least one polyfunctional epoxide monomer or oligomer comprises a siloxane that has an epoxy equivalent weight of greater than about 300 g/mole epoxy.

62. The holographic recording media of claim 56, wherein the at least one monomer or oligomer is represented by structural formulas (XXX) 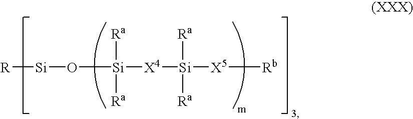
wherein R is a substituted or unsubstituted aliphatic group, a substituted or unsubstituted aryl group or is a group represented by the following structural formulas: 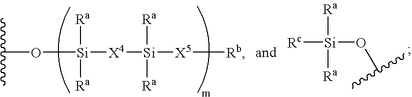
or structural formula (XXXII): 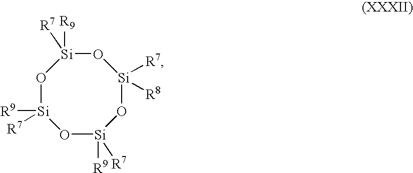
wherein:
X⁴ and X⁵ are each independently each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted 15 diaryl amino group;
each Y₁ is independently a covalent bond, or an optionally substituted C1-C12 alkylene group or optionally substituted C3-C12 cycloalkylene or an optionally substituted arylene group or optionally substituted C1-C12 arylalkylene;
each R^{a} is, independently, a substituted or unsubstituted aliphatic group or a substituted or unsubstituted aryl group;
each R^{b} is an aliphatic group substituted with an epoxide;
R^{c} is H, an unsubstituted aliphatic group, a substituted aliphatic group, an unsubstituted aryl group, a substituted aryl group, a substituted siloxane group, an unsubstituted siloxane group, a substituted polysiloxane group or an unsubstituted polysiloxane group;
each group R⁷ is independently an unsubstituted aliphatic group, a substituted aliphatic group, an unsubstituted aryl group or a substituted aryl group;
each group R⁸ is R⁹, hydrogen, an alkenyl, a substituted or unsubstituted C1-C12 alkyl, C1-C12 cycloalkyl, aryl substituted C1-C12 alkyl or aryl or R^{Z}—(O—Y₁ )ᵣ₋, (R^{Z})₃—Si—(O—Si(R^{Z})₂)ₛ—Y₁₋, or (R^{Z})₃Si—(O—Si(R^{Z})₂)ₛ—O—;
each R₉ is independently represented by the following structural formula: 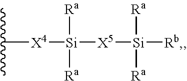
m is 1,2,3 or4;
r is an integer from 1 to 10; and
s is 0 or an integer from 1 to 8.

63. A method of recording holograms within a holographic recording media that comprises:
a) a photo acid generator compound (PAG) which produces acid when exposed to actinic radiation;
b) a dye which sensitizes the PAG to produce acid in response to a particular wavelength of light;
c) at least one monomer or oligomer which is capable of undergoing cationic polymerization initiated by the acid produced by PAG when exposed to actinic radiation; and
d) a binder of any of the compounds of claims 1 through 53, said method comprising the step of passing into the medium a reference beam of coherent actinic radiation to which the compound which produces acid when exposed to actinic radiation is sensitive and object beam of the same coherent actinic radiation, thereby forming within the medium an interference pattern and thereby recording a hologram within the medium.

64. The method of claim 63, wherein the at least one monomer or oligomer is represented by structural formulas (XXX) 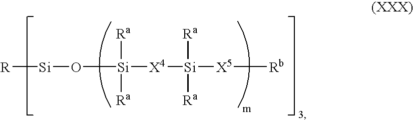
wherein R is a substituted or unsubstituted aliphatic group, a substituted or unsubstituted aryl group or is a group represented by the following structural formulas: 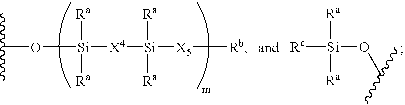
or structural formula (XXXII): 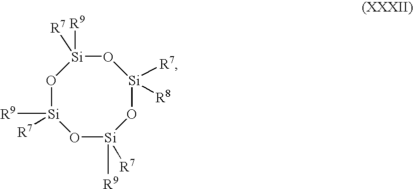
wherein:
X⁴ and X⁵ are each independently each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;
each Y₁ is independently a covalent bond, or an optionally substituted C1-C12 alkylene group or optionally substituted C3-C12 cycloalkylene or an optionally substituted arylene group or optionally substituted C1-C12 arylalkylene;
each R^{a} is, independently, a substituted or unsubstituted aliphatic group or a substituted or unsubstituted aryl group;
each R^{b} is an aliphatic group substituted with an epoxide;
R^{c} is H, an unsubstituted aliphatic group, a substituted aliphatic group, an unsubstituted aryl group, a substituted aryl group, a substituted siloxane group, an unsubstituted siloxane group, a substituted polysiloxane group or an unsubstituted polysiloxane group;
each group R⁷ is independently an unsubstituted aliphatic group, a substituted aliphatic group, an unsubstituted aryl group or a substituted aryl group;
each group R⁸ is R⁹, hydrogen, an alkenyl, a substituted or unsubstituted C1-C12 alkyl, C1-C12 cycloalkyl, aryl substituted C1-C12 alkyl or aryl or R^{Z}—(O—Y₁)ᵣ₋, (R^{Z})₃—Si—(O—Si(R^{Z})₂)ₛ—Y₁₋, or (R^{Z})₃Si—(O—Si(R^{Z})₂)ₛ—O—; each R₉ is independently represented by the following structural formula: 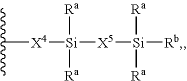
m is 1, 2, 3 or 4;
r is an integer from 1 to 10; and
s is 0 or an integer from 1 to 8.

65. A holographic recording media, comprising:
a) a photo acid generator compound (PAG) which produces acid when exposed to actinic radiation;
b) a dye which sensitizes the PAG to produce acid in response to a particular wavelength of light;
c) at least one monomer or oligomer which is capable of undergoing cationic polymerization initiated by the acid produced by PAG when exposed to actinic radiation; and
d) a binder of represented by the following formula: 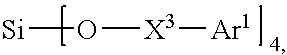
wherein:
X³ is X¹ or 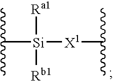
X¹, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁ —[O—Y₁]ₛ₋, —Y₁—Si(R^{Z})₂—Y₁₋, —Y₁—Si(R^{Z})₂—Y₁—O—Y₁—Si(R^{Z})₂—Y₁₋, or —Y₁—Si(R^{Z})₂—Y₁—Si(R^{Z})₂—Y₁₋;
R^{a1} and R^{b1}, for each occurrence, are independently an optionally substituted C1-C12 alkyl or optionally substituted C3-C12 cycloalkyl or an optionally substituted aryl or an optionally substituted heteroaryl;
Ar¹, for each occurrence, is independently an optionally substituted aryl or an optionally substituted heteroaryl;
each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;
each Y₁ is independently a covalent bond, or an optionally substituted C1-C12 alkylene group or optionally substituted C3-C12 cycloalkylene or an optionally substituted arylene group or optionally substituted C1-C12 arylalkylene; and
s is 0 or an integer from 1 to 8.

66. A method of recording holograms within a holographic recording media that comprises:
a) a photo acid generator compound (PAG) which produces acid when exposed to actinic radiation;
b) a dye which sensitizes the PAG to produce acid in response to a particular wavelength of light;
c) at least one monomer or oligomer which is capable of undergoing cationic polymerization initiated by the acid produced by PAG when exposed to actinic radiation; and
d) a binder of claim 76, said method comprising the step of passing into the medium a reference beam of coherent actinic radiation to which the compound which produces acid when exposed to actinic radiation is sensitive and object beam of the same coherent actinic radiation, thereby forming within the medium.

67. A composition, comprising a mixture of two or more compounds represented by structural formula (XV): 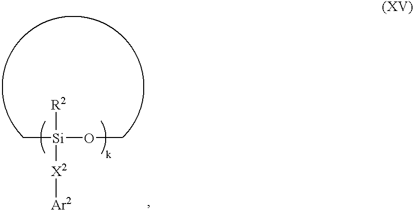
wherein:
R², for each occurrence, is independently an optionally substituted C1-C12 alkyl, an optionally substituted C3-C12 cycloalkyl, or an optionally substituted aryl;
X², for each occurrence, for each occurrence, is independently a covalent bond or an optionally substituted C1-C12 alkylene, optionally substituted C3-C12 cycloalkylene, optionally substituted C1-C12 arylalkylene, an optionally substituted arylene group, —Y₁ —[O—Y₁]ₛ₋, —Y₁ —Si(R^{Z})₂—Y₁₋, —Y₁ —Si(R^{Z})₂—Y₁—O—Y₁—Si(R^{Z})₂—Y₁₋, or —Y₁—Si(R^{Z})₂—Y₁ —Si(R^{Z})₂—Y₁₋;
Ar², for each occurrence, is independently an optionally substituted aryl or an optionally substituted heteroaryl;
each R^{Z} is independently an optionally substituted C1-C12 alkyl group, optionally substituted C3-C12 cycloalkyl alkyl group, or an aryl optionally substituted with a C1-C12 alkyl, C1-C12 alkene or C1-C12 alkyne group, a C1-C12 haloalkyl, a halogen, hydroxyl, a C1-C12 alkoxy group, optionally substituted aryloxy group or optionally substituted diaryl amino group;
each Y₁ is independently a covalent bond, or an optionally substituted C1-C12 alkylene group or optionally substituted C3-C12 cycloalkylene or an optionally substituted arylene group or optionally substituted C1-C12 arylalkylene;
k is3,4,5or6;and
s is 0 or an integer from 1 to 8, and further wherein at least two compounds of formula (XV) in the mixture have different values of variable k.

68. A composition, comprising a mixture of two or more compounds of claims 26 through 53, wherein at least two compounds in the mixture have different values of variable k.
